(19) United States
(12) Patent Application Publication
(10) Pub. No.: US 2012/0129335 A1
(43) Pub. Date: May 24, 2012

(54) METHOD OF MANUFACTURING SEMICONDUCTOR DEVICE

(75) Inventors: Masamitsu IKUMO, Yokohama (JP); Hiroyuki Yoda, Yokohama (JP); Yoshito Akutagawa, Yokohama (JP)

(73) Assignee: FUJITSU SEMICONDUCTOR LIMITED, Yokohama-shi (JP)

(21) Appl. No.: 13/193,569

(22) Filed: Jul. 28, 2011

(30) Foreign Application Priority Data
Nov. 22, 2010 (JP) 2010-260117

(51) Int. Cl. H01L 21/283

(52) U.S. Cl. 438/614; 257/E21.159

(57) ABSTRACT

A method of manufacturing a semiconductor device including the following steps: forming an insulator layer over a first conductor over a semiconductor substrate; forming a barrier layer to coat the surface of the insulator layer; forming a second conductor over the barrier layer; melting the second conductor in an atmosphere containing either hydrogen or carboxylic acid in a condition that the surface of the insulator layer over the first conductor is coated with the barrier layer; and removing the barrier layer partially from the surface of the insulator layer with the second conductor as a mask.

### CROSS-REFERENCE TO RELATED APPLICATION

This application is based upon and claims the benefit of priority of the prior Japanese Patent Application No. 2010-260117, filed on Nov. 22, 2010, the entire contents of which are incorporated herein by reference.

### FIELD

The embodiments discussed herein are related to a method of manufacturing a semiconductor device.

### BACKGROUND

Semiconductor manufacturing frequently involves reflow soldering. Reflow soldering is a process in which a solder body is formed and molten for bump formation and circuit mounting. Reflow of a semiconductor device can be accomplished in a variety of ways. One is the so-called flux reflow, which uses flux in a reflow process. Another is the so-called fluxless reflow, which uses hydrogen or carboxylic acid instead of flux.

Japanese Patent No. 3682227

Japanese Laid-open Patent Publication No. 2007-266381

Japanese Laid-open Patent Publication No. 06-190584

Japanese Laid-open Patent Publication No. 06-326448

Japanese Laid-open Patent Publication No. 2001-244283

However, when a reflow process using hydrogen or carboxylic acid is performed on a structure in which a conductor is coated with an insulator layer, such as a wiring layer of a semiconductor device, the adhesion between the conductor and the insulator layer is likely to be lower. Furthermore, this may reduce the reliability of the semiconductor device.

### SUMMARY

An aspect of the present invention is a method of manufacturing a semiconductor device, including the following steps: forming a first insulator layer on a first conductor over a semiconductor substrate; forming a barrier layer to coat the first insulator layer; forming a second conductor over the barrier layer; melting the second conductor in an atmosphere containing either hydrogen or carboxylic acid, in a condition that a surface of the first insulator layer is coated with the barrier layer; and removing the barrier layer partially with the second conductor as a mask.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates a method of manufacturing a semiconductor device;

FIG. 2 illustrates a semiconductor substrate including a wiring layer formed thereon;

FIGS. 3A and 3B illustrate a step of forming a pad and an insulator layer according to a first embodiment;

FIGS. 4A and 4B illustrate a step of forming a first barrier layer according to the first embodiment;

FIGS. 5A and 5B illustrate a step of forming a first electrode layer according to the first embodiment;

FIGS. 6A and 6B illustrate a step of forming a first resist according to the first embodiment;

FIGS. 7A and 7B illustrate a step of forming a redistribution layer according to the first embodiment;

FIGS. 8A and 8B illustrate a step of etching a barrier layer and an electrode layer according to the first embodiment;

FIGS. 9A and 9B illustrate a step of forming another insulator layer according to the first embodiment;

FIGS. 10A and 10B illustrate a step of forming a second barrier layer according to the first embodiment;

FIGS. 11A and 11B illustrate a step of forming a second electrode layer according to the first embodiment;

FIGS. 12A and 12B illustrate a step of forming a second resist according to the first embodiment;

FIGS. 13A and 13B illustrate a step of forming a bump according to the first embodiment;

FIGS. 14A and 14B illustrate a step of removing a resist according to the first embodiment;

FIGS. 15A and 15B illustrate a step of etching an electrode layer according to the first embodiment;

FIGS. 16A and 16B illustrate a step of performing a reflow process according to the first embodiment;

FIGS. 17A and 17B illustrate a step of etching a barrier layer according to the first embodiment;

FIGS. 18A and 18B illustrate a step of performing dry etching according to the first embodiment;

FIGS. 19A and 19B illustrate a step of etching an electrode layer and a barrier layer;

FIGS. 20A and 20B illustrate a step of performing a reflow process;

FIGS. 21A and 21B illustrate a step of forming a pad and an insulator layer according to the second embodiment;

FIGS. 22A and 22B illustrate a step of forming a barrier layer according to the second embodiment;

FIGS. 23A and 23B illustrate a step of forming an electrode layer according to the second embodiment;

FIGS. 24A and 24B illustrate a step of forming a resist according to the second embodiment;

FIGS. 25A and 25B illustrate a step of forming a bump according to the second embodiment;

FIGS. 26A and 26B illustrate a step of removing a resist according to the second embodiment;

FIGS. 27A and 27B illustrate a step of etching an electrode layer according to the second embodiment;

FIGS. 28A and 28B illustrate a step of performing a reflow process according to the second embodiment;

FIGS. 29A and 29B illustrate a step of etching a barrier layer according to the second embodiment;

FIGS. 30A and 30B illustrate a step of performing a dry-etching process according to the second embodiment;

FIGS. 31A and 31B illustrate another step of etching an electrode layer and a barrier layer;

FIGS. 32A and 32B illustrate another step of performing a reflow process;

FIGS. 33A and 33B illustrate a step of forming a resist according to the third embodiment;

FIGS. 34A and 34B illustrate a step of forming a pillar bump according to the third embodiment;

FIGS. 35A and 35B illustrate a step of removing a resist according to the third embodiment;

FIGS. 36A and 36B illustrate a step of etching an electrode layer according to the third embodiment;

FIGS. 37A and 37B illustrate a step of performing a reflow process according to the third embodiment;

FIGS. 38A and 38B illustrate a step of etching a barrier layer according to the third embodiment;

FIGS. 39A and 39B illustrate a step of performing a dry-etching process according to the third embodiment;

FIGS. 40A and 40B illustrate still another step of etching an electrode layer and a barrier layer;

FIGS. 41A and 41B illustrate still another step of performing a reflow process;

FIGS. 42A to 42C illustrate another step of forming a bump according to the first embodiment; and

FIGS. 43A to 43C illustrate another step of forming a bump according to the second embodiment.

### DESCRIPTION OF EMBODIMENTS

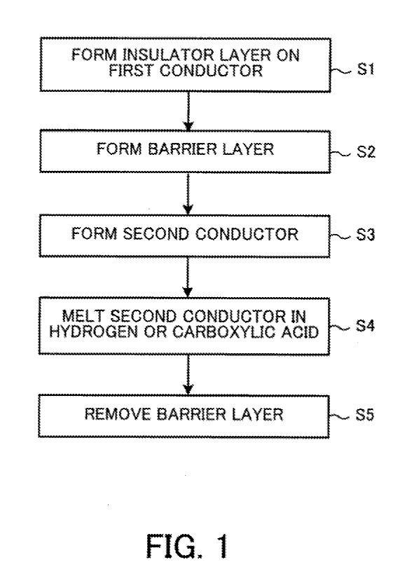

FIG. 1 illustrates an example of a method of manufacturing a semiconductor device.

First, an insulator layer is formed on a first conductor which is formed over a semiconductor substrate (step S1). Before the first conductor is formed, the semiconductor substrate may incorporate elements such as transistors. Examples of the first conductor include an electrical interconnection of a wiring layer formed over a semiconductor substrate; a pad, and a redistribution layer such as a wafer-level package. Such a first conductor is formed on the semiconductor substrate with a predetermined pattern. The insulator layer formed on the first conductor is made of, for example, an organic insulating material. An inorganic insulating material may also be used for the insulator layer. The insulator layer protects the first conductor and the structure below the first conductor.

After the insulator layer is formed on the first conductor, a barrier layer is formed to coat the insulator layer (step S2). The barrier layer suppresses the permeation of the hydrogen or the carboxylic acid used for a reflow process. Examples of the barrier layer include a metal layer and an electrically conductive layer such as a barrier metal layer.

After the barrier layer is formed, a second conductor is formed over the barrier layer (step S3). The second conductor is, for example, a projecting electrode (bump) to become an external connection terminal of the semiconductor device. In this case, the second conductor is made of solder material.

After the second conductor is formed, the second conductor is molten in an atmosphere containing either hydrogen or carboxylic acid, in a condition that a surface of the insulator layer is coated with the barrier layer (step S4), and the second conductor is solidified. Specifically, a reflow process is performed on the second conductor using hydrogen or carboxylic acid.

After the second conductor is molten and then solidified, the barrier layer is removed with the second conductor with a mask (step S5). The barrier layer is removed, for example, by etching.

In the manufacturing flow illustrated in FIG. 1, while the second conductor is being molten in an atmosphere containing either hydrogen or carboxylic acid, the insulator layer is coated with the barrier layer. The barrier layer is removed from the surface of the insulator layer with the second conductor as a mask after the second conductor is molten and solidified. According to the manufacturing flow, the adhesion between the insulator layer and the first conductor immediately below the insulator layer is prevented from becoming lower.

Hereinafter, a method of manufacturing a semiconductor device is described in detail.

A description is given for a first embodiment.

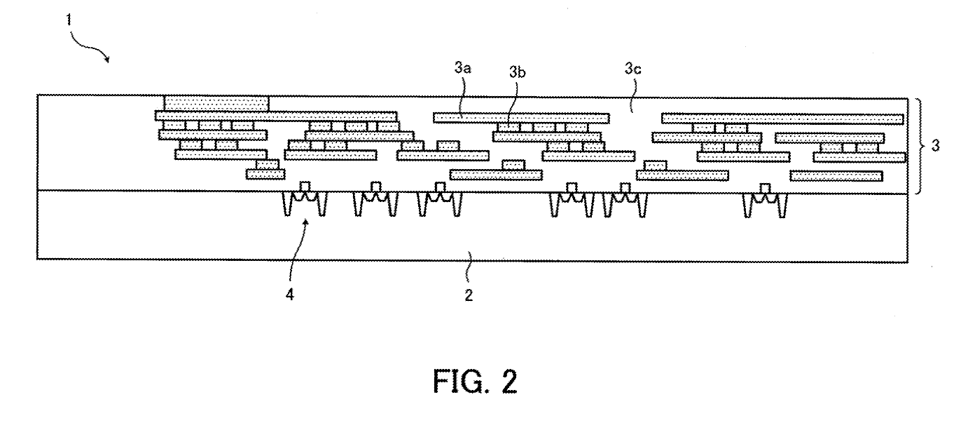

FIG. 2 illustrates a semiconductor substrate including a wiring layer formed thereon.

Referring to FIG. 2, a circuit board 1 includes a semiconductor substrate 2 and a wiring layer 3 formed on the semiconductor substrate 2.

The semiconductor substrate 2 is made of a semiconductor material such as silicon (Si). As illustrated in FIG. 2, transistors 4 are provided in the semiconductor substrate 2. In FIG. 2, a plurality of metal oxide semiconductor (MOS) transistors are employed as the transistors 4. The semiconductor substrate 2 may also include other elements such as capacitors, resistors, or any combination thereof.

The wiring layer 3 is formed on the semiconductor substrate 2. FIG. 2 illustrates electrical interconnections as the wiring layer 3. The wiring layer includes electrical interconnections 3a having different patterns; vias 3b interconnecting the electrical interconnections 3a; and an insulator layer 3c coating the electrical interconnections 3a and the vias 3b. A pad is formed on the wiring layer 3 to be connected electrically to a corresponding transistor 4 through the corresponding electrical interconnection 3a and the corresponding via 3b.

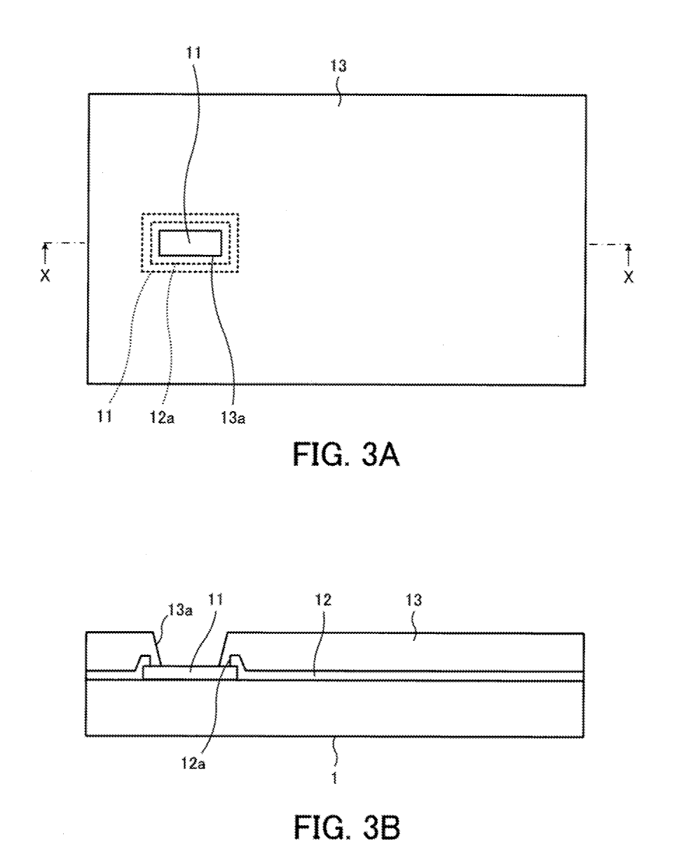

In the first embodiment, referring to FIGS. 3A and 3B to 20A and 20B, a method of forming a redistribution layer and a bump on the circuit board 1 illustrated in FIG. 2.

FIGS. 3A and 3B to 20A and 20B schematically illustrate each step of forming a redistribution layer and a bump. FIGS. 3A to 20A are plan views of a substantial part of an unfinished semiconductor device during manufacture according to the first embodiment. FIGS. 3B to 20B are sectional views taken along the line X-X in FIGS. 3A to 20A. In FIGS. 3A and 3B to 20A and 20B, the internal configuration of the circuit board 1 illustrated in FIG. 2 is omitted for the sake of convenience.

FIGS. 3A and 3B illustrate a step of forming a pad and an insulator layer according to the first embodiment.

First, a pad 11 is formed on a circuit board 1. The pad 11 connects electrically to a corresponding transistor 4 formed in the circuit board 1. The pad 11 is made of aluminum (Al), copper (Cu), a conductive material containing Al, a conductive material containing Cu, or the like.

After the pad 11 is formed, an insulator layer 12 is formed on the circuit board 1. The insulator layer 12 has an opening 12a so that a region of the pad 11 appears therethrough. The insulator layer 12 is made of, for example, an inorganic insulating material. The insulator layer 12 protects the pad 11 and the circuit board 1.

After the pad 11 and the insulator layer 12 are formed, an insulator layer 13 is formed on the circuit board 1. The insulator layer 13 has an opening 13a so that a region of the pad 11 appears therethrough. The insulator layer 13 improves the reliability of a finished semiconductor device to be formed and the electrical characteristics thereof.

The type of the insulator layer 13 may vary according to the reliability of a finished semiconductor device to be formed, the upper temperature limits of the elements in the circuit board 1, and the infrastructure of the factory where the semiconductor device is manufactured. The insulator layer 13 may be made of, for example, an organic insulating material such as polyimide, poly(p-phenylenebenzobisoxazole) (PBO), or epoxy resin.

The thickness of the insulator layer 13 may vary according to the intended use of the semiconductor device to be formed. For example, the insulator layer 13 may be 4 μm to 15 μm thick.

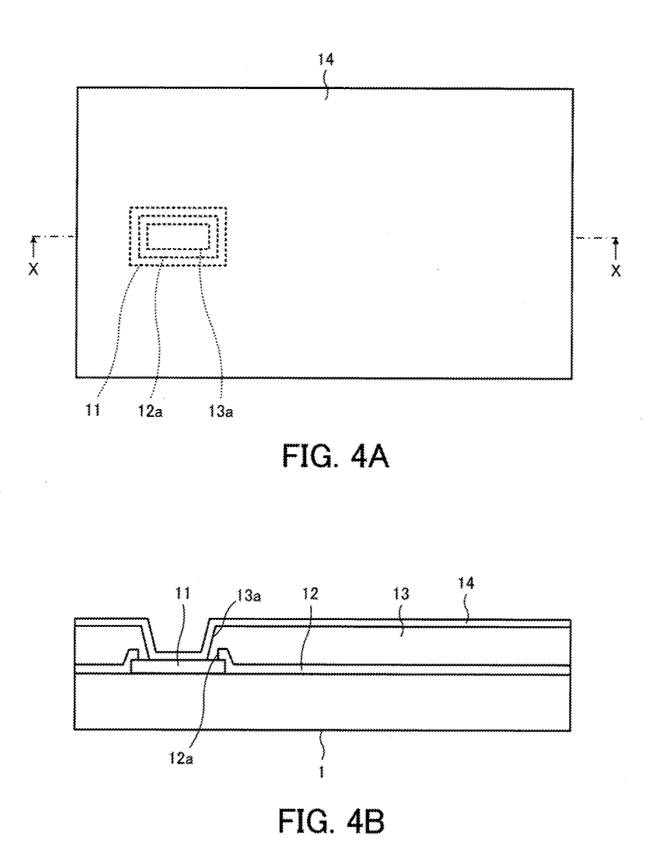

FIGS. 4A and 4B illustrate a step of forming a first barrier layer according to the first embodiment.

After the insulator layer 13 is formed, a barrier layer 14 is formed so as to coat the insulator layer 13. The barrier layer 14 is made of, for example, a barrier metal material. The barrier layer 14 is formed on the inner surface of the opening 13a of the insulator layer 13 (specifically, the top face of the pad 11 positioned in the bottom of the opening 13a, and the surface of the sidewalls of the opening 13a of the insulator layer 13) and on the insulator layer 13.

The barrier layer 14 is made of, for example, titanium (Ti) or titanium tungsten (TiW). The barrier layer 14 is, for example, 100 nm to 300 nm thick. The barrier layer 14 serves to prevent undesirable leakage of the material of a redistribution layer to be formed later onto the pad 11. The barrier layer 14 also serves to have the interconnection between the redistribution layer and the pad 11, and to improve the adhesion therebetween.

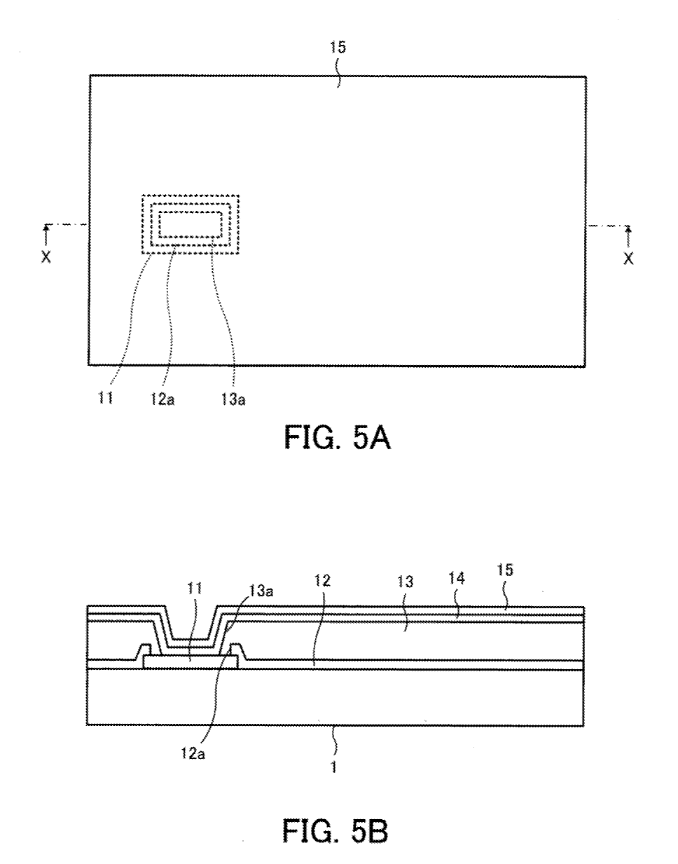

FIGS. 5A and 5B illustrate a step of forming a first electrode layer according to the first embodiment.

After the barrier layer 14 is formed, an electrode layer 15 is formed. Electric power is supplied through the electrode layer 15 in an electroplating step to be described later.

The electrode layer 15 is an electrically conductive layer made of Cu or the like, formed by a method such as plating or sputtering. The thickness of the electrode layer 15 may cause the nonuniformity of plating thickness, so the thickness of the electrode layer 15 is determined depending on the condition of the base metal (electrode layer 15) before electroplating. The thickness of the electrode layer 15 is, for example, 200 nm to 500 nm.

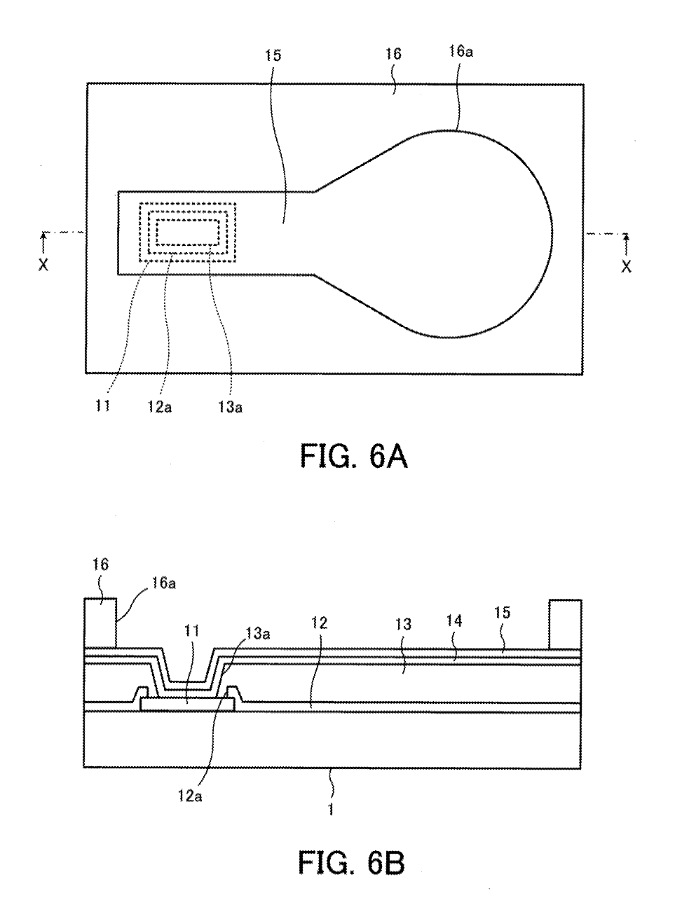

FIGS. 6A and 6B illustrate a step of forming a resist according to the first embodiment.

After the electrode layer 15 is formed, a resist 16 is formed. The resist 16 is formed by depositing a predetermined resist material on the surface of the electrode layer 15 with a thickness of 5 μm to 14 μm. An opening 16a is then formed by exposing and developing the resist 16 so that the region where a redistribution layer is to be formed appears therethrough.

The material used as the resist 16 is not limited to a specific type of material, as long as the material fits for the material of the electrode layer 15. In this case, as will be described later, Cu is employed for a redistribution layer, and novolac positive resist is employed as the resist 16. The resist 16 may be liquid or dry film.

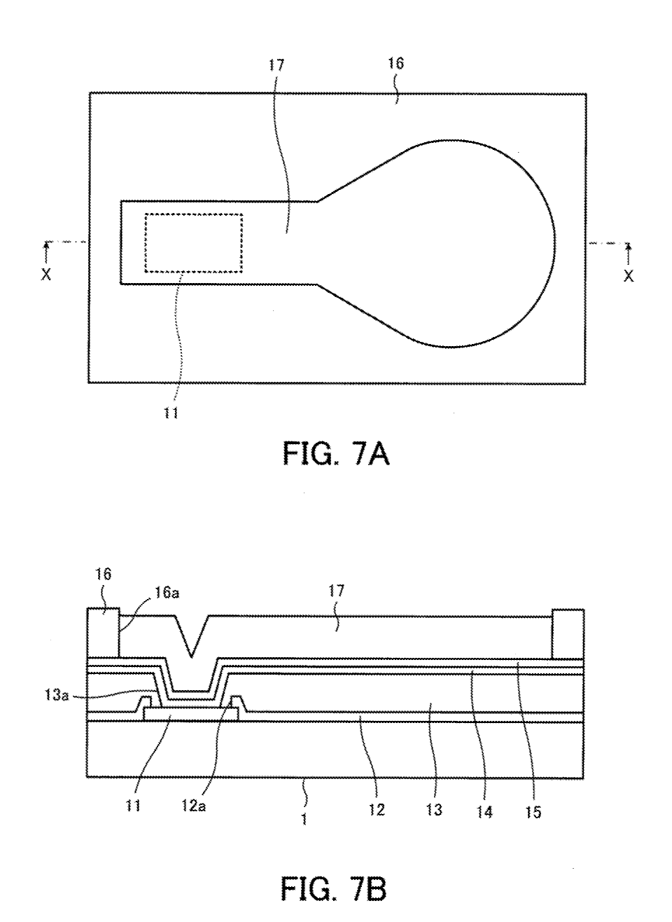

FIGS. 7A and 7B illustrate a step of forming a redistribution layer according to the first embodiment.

After the resist 16 and the opening 16a are formed, a redistribution layer 17 for electrical interconnection is formed by electroplating in the opening 16a of the resist 16.

The redistribution layer 17 is made of Cu, a conductive material containing Cu, or the like. The redistribution layer 17 may be made of Al, a conductive material containing Al, or the like. In this case, the redistribution layer 17 is formed of Cu by electroplating. About 1 A/dm² to 3 A/dm² of current density is employed for electroplating in this case. The thickness of the redistribution layer 17 is determined depending on the intended use of a semiconductor device to be formed. For example, the redistribution layer 17 has a thickness of 5 μm.

After the redistribution layer 17 is formed by electroplating, the resist 16 stripped from the electrode layer 15. In this case, a stripper which fits for the material of the resist 16 is employed. For example, if a novolac positive resist is employed as the resist 16, butyl acetate, propylene glycol monomethyl ether (PGME), propylene glycol monomethyl ether acetate (PGMEA) or the like is employed as a stripper.

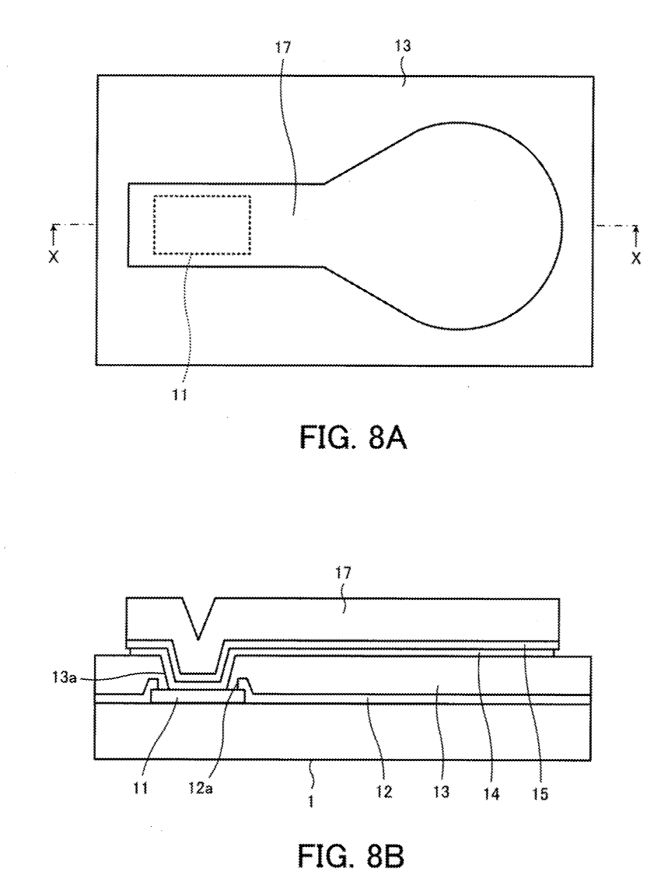

In FIG. 7A and the subsequent FIGS. 8A to 20A, the openings 12a and 13a of the insulator layers 12 and 13 are omitted for the sake of convenience.

FIGS. 8A and 8B illustrate a step of etching the barrier layer and the electrode layer according to the first embodiment.

After the resist 16 is stripped, the electrode layer 15 and the barrier layer 14 appear. The electrode layer 15 and the barrier layer 14 are then partially removed by etching with the redistribution layer 17 as a mask. This etching process is carried out, for example, by wet etching. The electrode layer 15 is wet-etched with an etchant containing sulfuric acid, acetic acid, and the like. The barrier layer 14 is wet-etched with an etchant containing hydrofluoric acid, hydrogen peroxide, and the like. The etchant for the barrier layer 14 does not etch the insulator layer 13 deposited immediately below the barrier layer 14, nor etch the insulator layer 13 excessively.

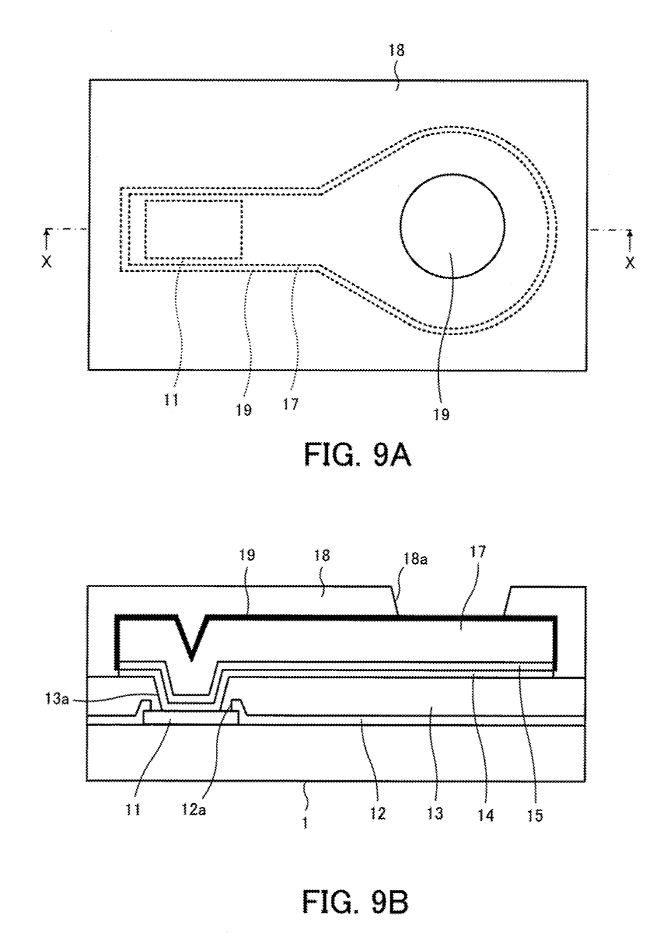

FIGS. 9A and 9B illustrate a step of forming an insulator layer according to the first embodiment. After the electrode layer 15 and the barrier layer 14 are etched, an insulator layer 18 is formed. The insulator layer 18 is formed to cover the entire surface of the redistribution layer 17. The insulator layer 18 has an opening 18a so that a region of the redistribution layer 17 appears therethrough. A bump is formed later in this region.

The type of the insulator layer 18 may vary according to the reliability of a finished semiconductor device to be obtained, the upper temperature limits of the elements in the circuit board 1, and the infrastructure of the factory where the semiconductor device is manufactured. For example, the insulator layer 18 is an organic insulator layer. An organic insulator layer may be made of an organic insulating material such as polyimide, PBO, or epoxy resin. In order to form an organic insulator layer, first, an organic insulating material is deposited on the redistribution layer 17. An opening is then formed by exposing and developing the organic insulating material. Finally, the organic insulating material is annealed in the range of 300° C. to 380° C. in a nitrogen atmosphere containing 100 ppm of oxygen or less.

The insulator layer 18 is thicker than the redistribution layer 17 by 1 μm. For example, if the redistribution layer 17 has a thickness of 5 μm, the insulator layer 18 is 6 μm or thicker.

When the insulator layer 18 is formed, an oxide film 19 is also formed on the surface of the redistribution layer 17. Oxygen sources of the oxide film 19 include the oxygen contained in the environment where the insulator layer 18 is formed (during annealing, etc), the oxygen contained in the insulator layer 18 or the material thereof, and oxygen from the atmosphere. Since the oxide film 19 is interposed between the redistribution layer 17 and the insulator layer 18, the adhesion between the redistribution layer 17 and the insulator layer 18 is improved in comparison with a case where no oxide film 19 is interposed.

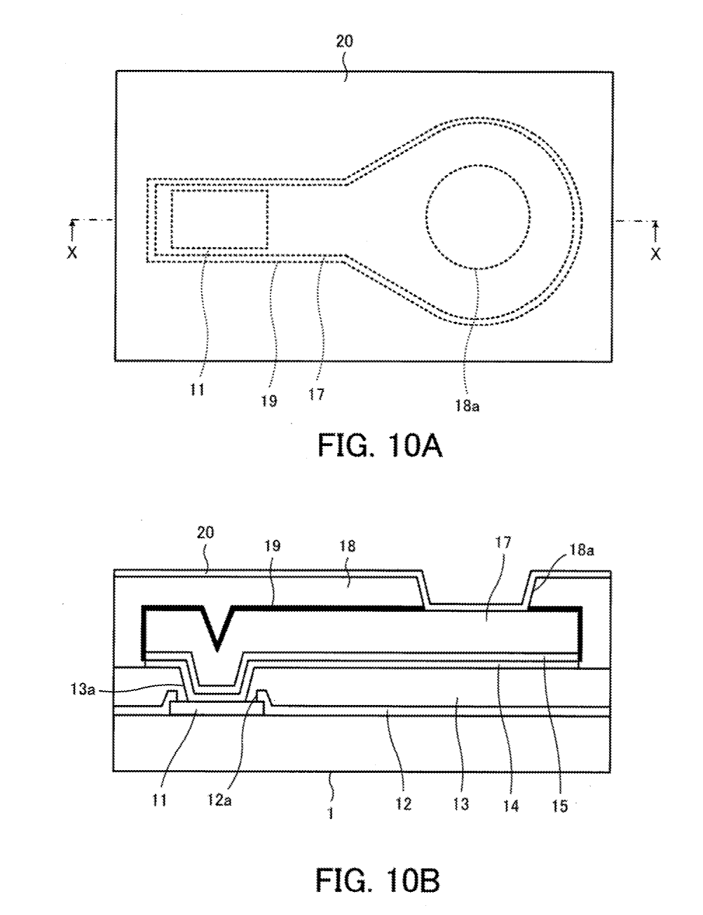

FIGS. 10A and 10B illustrate a step of forming a second barrier layer according to the first embodiment.

After the insulator layer 18 and the opening 18a are formed, a barrier layer 20, for example, a barrier metal layer, is formed to coat the entire surface of the insulator layer 18. The barrier layer 20 serves to prevent undesirable leakage of the material of a bump to be formed later onto the redistribution layer 17. The barrier layer 20 also serves to have the interconnection between the bump and the redistribution layer 17, and to improve the adhesion therebetween.

Before the barrier layer 20 is formed, the oxide film 19 formed on the redistribution layer 17 in the opening 18a is removed. For example, the oxide film is removed by reverse sputtering, and the barrier layer 20 is then deposited by sputtering.

The barrier layer 20 is formed on the inner surface of the opening 18a of the insulator layer 18 (specifically, the top face of the redistribution layer 17 positioned in the bottom of the opening 18a, and the surface of the sidewalls of the opening 18a of the insulator layer 18), and on the insulator layer 18. The barrier layer 20 is made of, for example, Ti or TiW. The barrier layer 20 is, for example, 100 nm to 300 nm thick. If the barrier layer 20 is thinner than 100 nm, this may cause the nonuniformity of deposition thickness of the barrier layer 20 on the inner surface of the opening 18a, and on the entire surface of the insulator layer 18, depending on the shape of the opening 18a. On the other hand, if the barrier layer 20 is thicker than 300 nm, a greater stress is generated in the insulator layer 18 deposited immediately below the barrier layer 20, cracks are likely to occur in the insulator layer 18.

The barrier layer 20 is made of a material which prevents the permeation of hydrogen or carboxylic acid used in a reflow process to be described later.

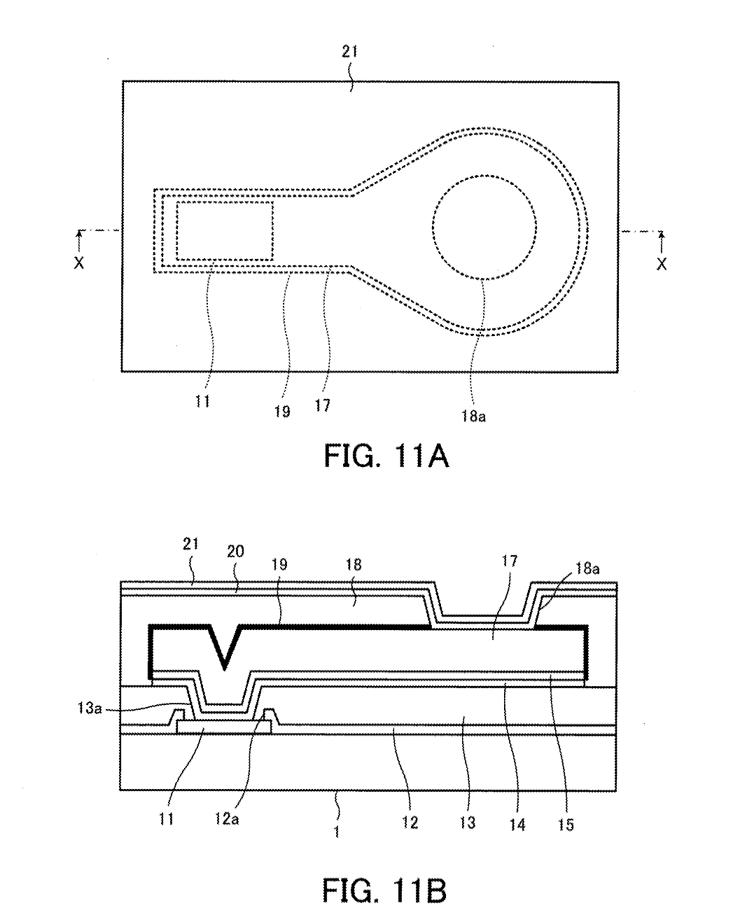

FIGS. 11A and 11B illustrate a step of forming a second electrode layer according to the first embodiment.

After the barrier layer 20 is formed, an electrode layer 21 is formed. Electric power is supplied through the electrode layer 21 in an electroplating step to be described later.

The electrode layer 21 is an electrically conductive layer made of Cu or the like, formed by a method such as plating or sputtering. The thickness of the electrode layer 21 may cause the nonuniformity of plating thickness, so the thickness of the electrode layer 21 is determined depending on the condition of the base metal (electrode layer 21) before electroplating. The thickness of the electrode layer 21 is, for example, 200 nm to 500 nm.

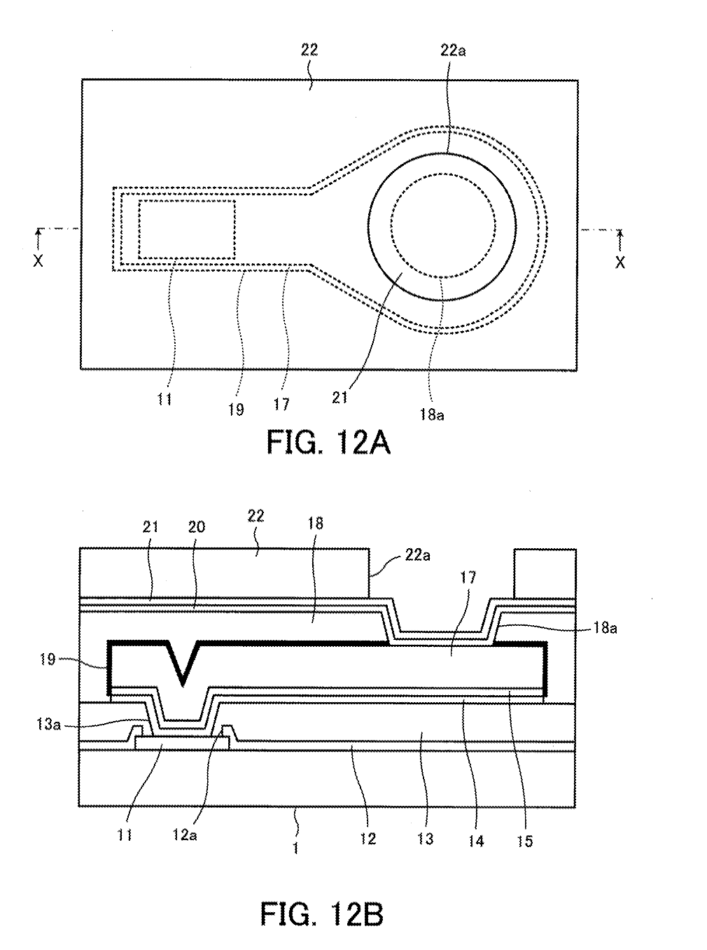

FIGS. 12A and 12B illustrate a step of forming a second resist according to the first embodiment.

After the electrode layer 21 is formed, a resist 22 is formed. The resist 22 is formed by depositing a predetermined resist material on the electrode layer 21 with a predetermined thickness. An opening 22a is then formed by exposing and developing the resist 22 so that the region where a bump is to be formed appears therethrough.

The material used as the resist 22 is not limited to a specific type of material, as long as the material fits for the material of the electrode layer 21. In this case, a novolac positive resist is employed as the resist 22. The thickness of the resist 22 may vary depending on the height of a bump to be obtained finally and the forming conditions thereof. For example, the thickness of the resist 22 is about 50 μm or thinner. The resist 22 may be liquid or dry film

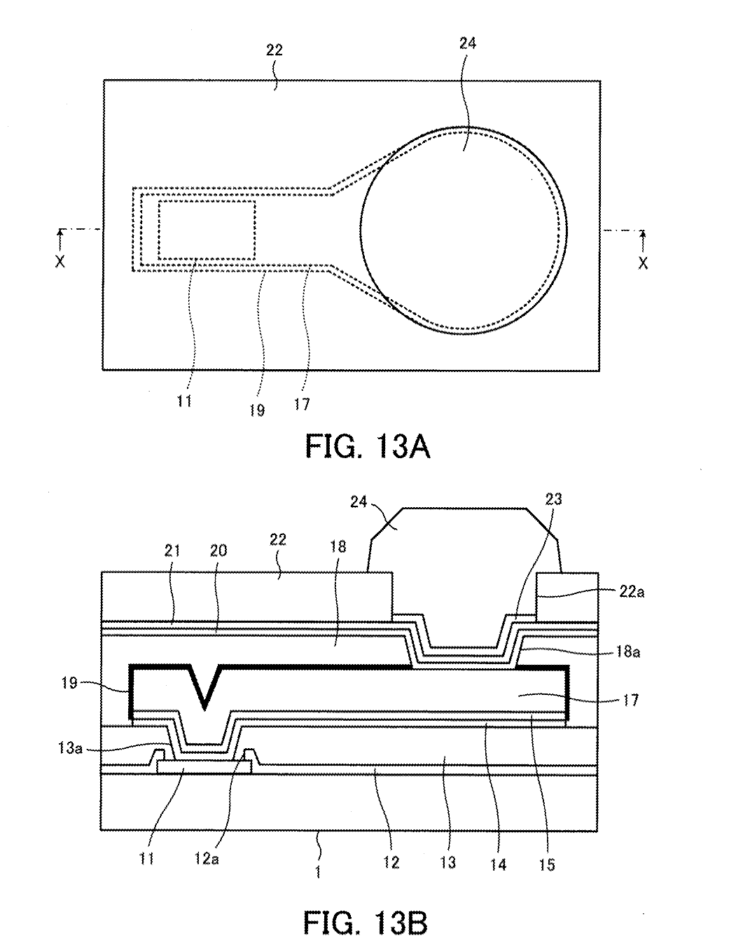

FIGS. 13A and 13B illustrate a step of forming a bump according to the first embodiment.

After the resist 22 and the opening 22a are formed, an under bump metal (UBM) 23 and a bump 24 are formed. In this case, both the UBM 23 and the bump 24 are formed by electroplating.

The UBM 23 is formed by electroplating on a region of the electrode layer 21, which appears through the opening 22a of the resist 22. Electric power for the electroplating is supplied through the electrode layer 21. The UBM 23 is made of, for example, nickel (Ni). The thickness of the UBM 23 is determined depending on the material of the bump 24 to be formed later. For example, in the case where the bump 24 is formed by soldering, the thickness of the UBM 23 is about in the range of 2 μm to 5 μm. Next, suppose that the UBM 23 is made of Ni, and the bump 24 is formed by soldering. High melting point solder materials have a low Sn level, so the UBM 23 tends to be thinner. On the other hand, tin-silver (SnAg) solder materials have a high Sn level, so the UBM 23 tends to be thicker.

The bump 24 is formed on the UBM 23 in the opening 22a of the resist 22 by electroplating. Electric power for the electroplating is supplied through the electrode layer 21 and the UBM 23. The bump 24 is made of, for example, a solder material. In this case, SnAg solder material is employed. The bump 24 is formed in the opening 22a of the resist 22. The bump 24 is high enough to protrude from the resist 22. The electroplating thickness of the bump 24 is determined depending on the height of the bump 24 to be obtained finally after a reflow process. According to the height of the bump 24 to be obtained finally, electroplating conditions and the thickness (see FIGS. 12A and 12B) of the resist 22 are determined.

The above description relates to the case in which both the UBM 23 and the bump 24 are formed by electroplating. However, a bump may be formed by putting a solder ball on a UBM 23 formed by electroplating. In this case, the thickness of a resist 22 (FIGS. 12A and 12B) for forming the UBM 23 may be 10 μm or thinner.

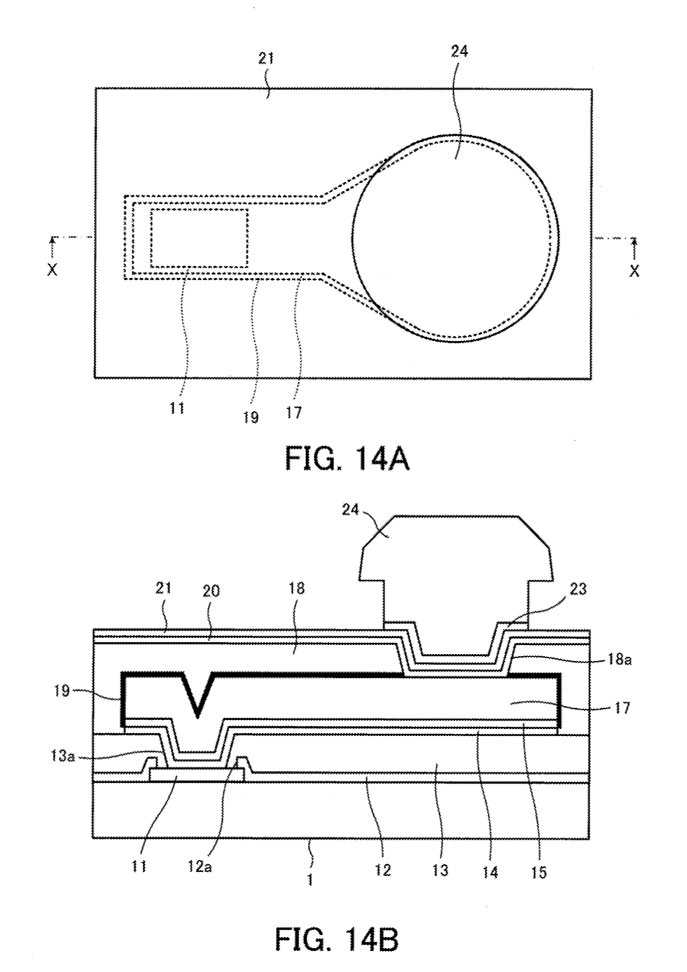

In FIG. 13A and the subsequent FIGS. 14A to 20A, the opening 18a of the insulator layer 18 is omitted for the sake of convenience.

FIGS. 14A and 14B illustrate a step of removing the resist according to the first embodiment.

After the UBM 23 and the bump 24 are formed, the resist 22 is stripped from the electrode layer 21. In this case, a stripper which fits for the material of the resist 22 is employed. For example, if a novolac positive resist is employed as the resist 22, butyl acetate, PGME, PGMEA or the like is employed as a stripper. After the resist 22 is stripped from the electrode layer 21, the bump 24 and the UBM 23 also appear.

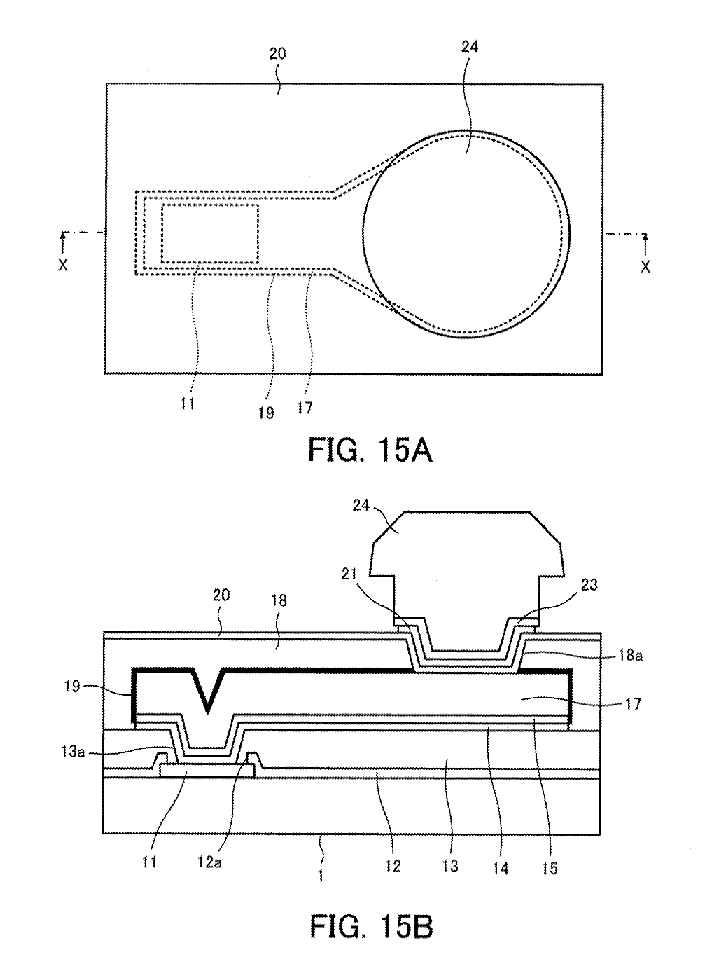

FIGS. 15A and 15B illustrate a step of etching the electrode layer according to the first embodiment.

After the resist 22 is stripped, the electrode layer 21 appears. The electrode layer 21 is then partially removed by etching with the UBM 23 and the bump 24 as masks. This etching process is carried out, for example, by wet etching. The electrode layer 21 is wet-etched with an etchant containing sulfuric acid, acetic acid, and the like. The etchant for electrode layer 21 etches the electrode layer 21 selectively, relative to the barrier layer 20.

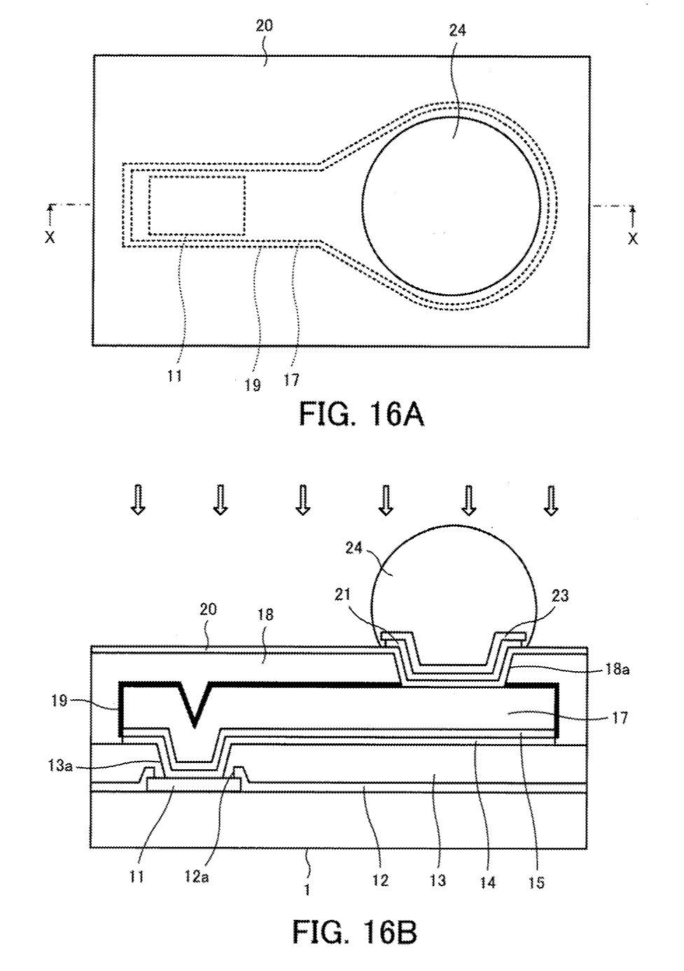

FIGS. 16A and 16B illustrate a step of performing a reflow process according to the first embodiment.

After the electrode layer 21 is partially removed, a reflow process is performed in a condition that the surface of the insulator layer 18 is coated with the barrier layer 20 (illustrated schematically by thick arrows in FIG. 16B). This process is the so-called fluxless reflow, which is performed in an atmosphere containing hydrogen or carboxylic acid. A bump 24 is formed in the reflow process.

Examples of carboxylic acid used for the reflow process include formic acid, acetic acid, acrylic acid, propionic acid, butyric acid, caproic acid, oxalic acid, succinic acid, salicylic acid, malonic acid, enanthic acid, caplyric acid, pelargonic acid, lactic acid, or capric acid, or any combination thereof.

Taking formic acid as an example, the reflow process is described. First, the unfinished semiconductor device during manufacture is put in a chamber, and the pressure within the chamber is reduced to 10 Pa or lower. Next, formic acid is injected into the chamber. In this case, formic acid may be in liquid form or in gas form. Formic acid is injected so that the pressure becomes about 660 Pa to 8000 Pa after the formic acid injection. The temperature at the start of the formic acid injection is higher than the boiling point of formic acid, and lower than the melting point of the solder material employed for the bump 24. For example, if the bump 24 is made of SnAg solder material, the injection of formic acid is started at a temperature about in the range of 120° C. to 200° C. After that, the temperature is raised up to the melting point of the solder material or higher, so that the solder material becomes molten. The solder material keeps molten approximately in the range of 240° C. to 300° C. for 50 seconds to 400 seconds, although conditions vary according to the amount of the solder material, etc.

After the solder material becomes molten, the unfinished semiconductor device is kept approximately at 150° C. for 90 seconds to 150 seconds to remove the formic acid left in the chamber. The unfinished semiconductor device is then left to reach room temperature.

Before the reflow process, immediately after electroplating, the bump 24 has the appearance illustrated in FIGS. 15A and 15B. In the reflow process, the bump 24 is molten, caused to assume a semispherical shape as illustrated in FIGS. 16A and 16B due to surface tension of solder material, and then solidified.

In the first embodiment, an electrode layer is etched away as illustrated in FIGS. 15A and 15B before a reflow process using hydrogen or carboxylic acid, but no etching is performed on the barrier layer 20, which appears after the removal of the electrode layer 21. Specifically, in the reflow process, the surface of the insulator layer 18 is coated with the barrier layer 20. Therefore, the permeation of the hydrogen or the carboxylic acid used in the reflow process into the insulator layer 18 is prevented by the barrier layer 20.

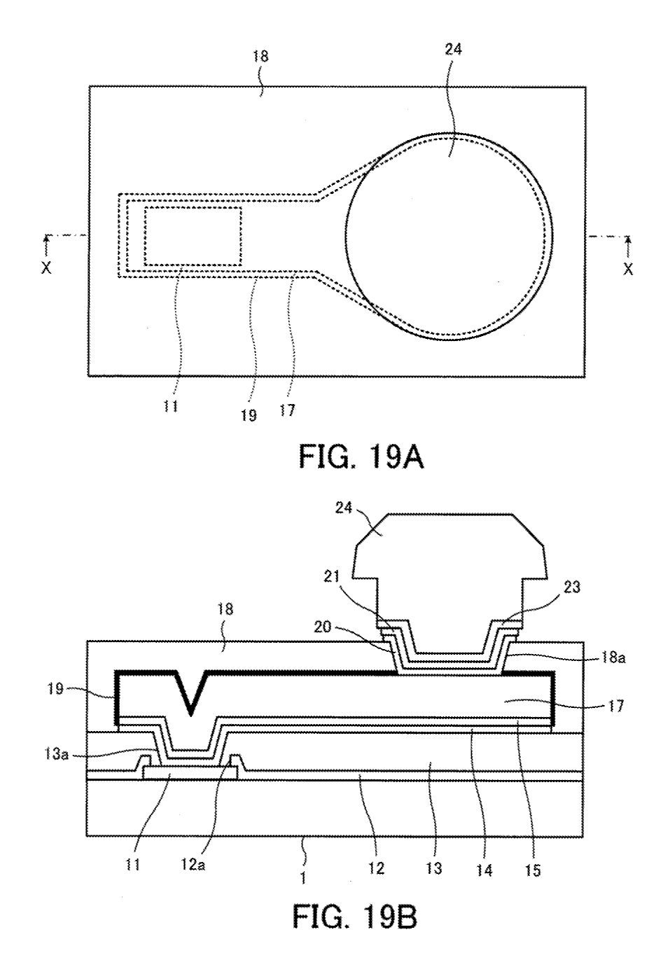

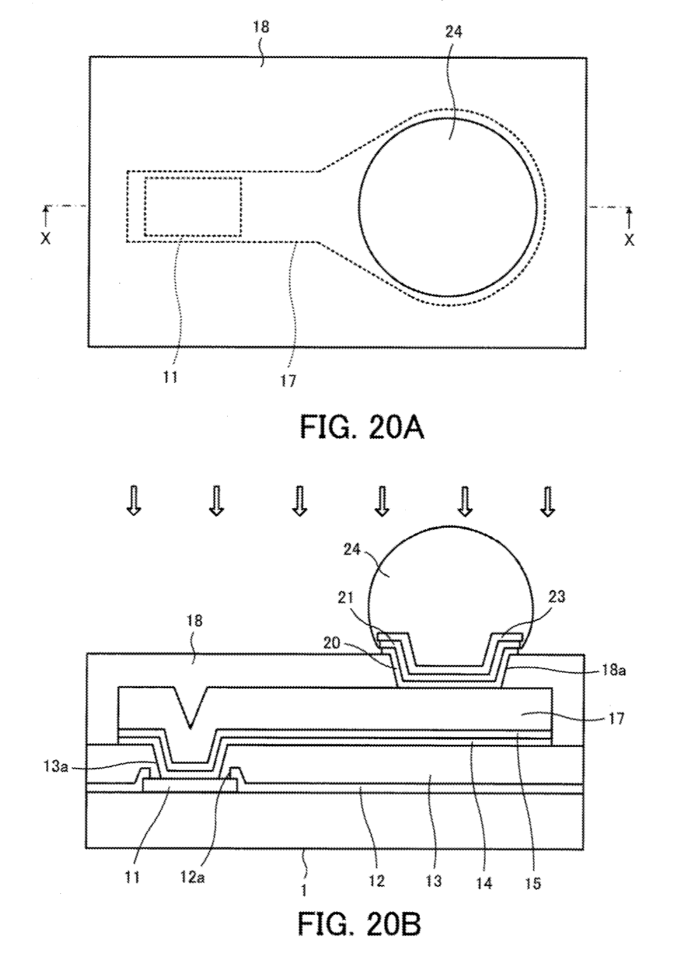

On the other hand, suppose that a barrier layer 20, which appears after the removal of an electrode layer 21, is partially removed from an insulator layer 18 before a reflow process using hydrogen or carboxylic acid as illustrated in FIGS. 19A and 19B. If a reflow process using hydrogen or carboxylic acid is performed here, a bump 24 is shaped into a semispherical shape as illustrated in FIGS. 20A and 20B. Since the barrier layer 20 is partially removed from the surface of the insulator layer 18, the hydrogen or the carboxylic acid used for reflow may permeate into the insulator layer 18 during the reflow process. When the hydrogen or the carboxylic acid reaches an oxide film 19 formed on the surface of a redistribution layer 17 through the insulator layer 18, the oxide film 19 may become reduced. Since the oxide film 19 is interposed between the redistribution layer 17 and the insulator layer 18, the adhesion between the redistribution layer 17 and the insulator layer 18 is relatively high. Therefore, if the oxide film 19 disappears due to reduction, the adhesion between the redistribution layer and the insulator layer 18 becomes lower. In some serious cases, stripping occurs at the interface between the redistribution layer 17 and the insulator layer 18.

In contrast, in the first embodiment, as illustrated in FIGS. 15A and 15B, since the barrier layer 20, which appears after the removal of the electrode layer 21, is left on the insulator layer 18, the permeation of the hydrogen or the carboxylic acid used in the reflow process into the insulator layer 18 is prevented. As a result of that, as illustrated in FIGS. 16A and 16B, since the reduction of the oxide film 19 caused by hydrogen or carboxylic acid is suppressed, the adhesion between the redistribution layer 17 and the insulator layer 18 is prevented from becoming lower.

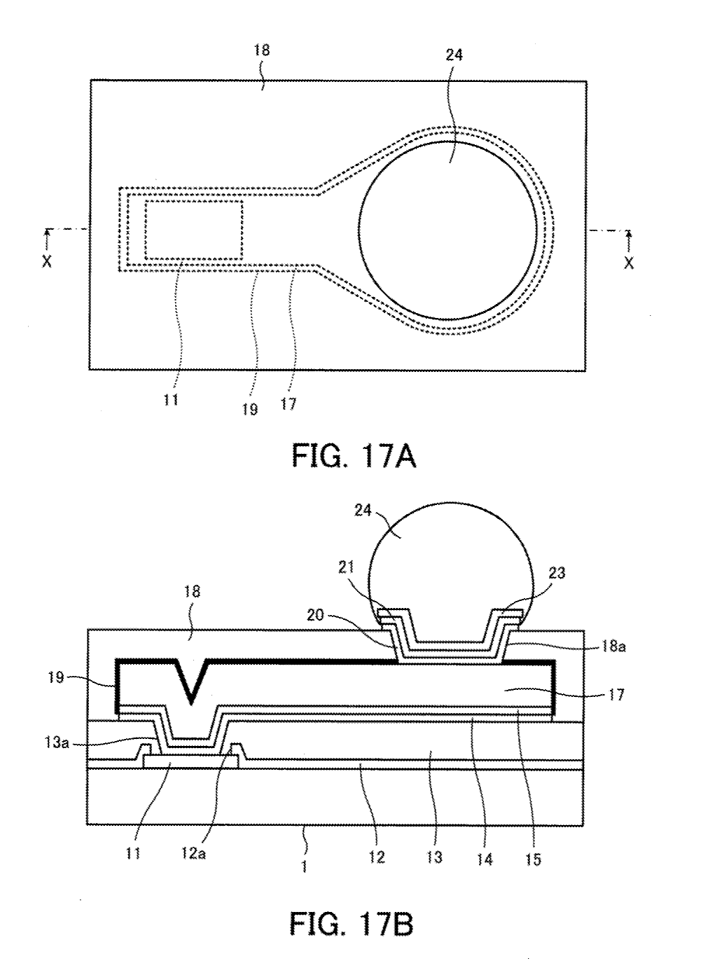

FIGS. 17A and 17B illustrate a step of etching the barrier layer according to the first embodiment.

After the reflow process is performed by using hydrogen or carboxylic acid in a condition that the surface of the insulator layer 18 is coated with the barrier layer 20, the barrier layer 20 is partially removed by etching. This etching process is carried out, for example, by wet etching. The barrier layer 20 is wet-etched with an etchant containing hydrofluoric acid, hydrogen peroxide, and the like. As an etchant for the barrier layer 20, an etchant that does not etch the insulator layer 18 deposited immediately below the barrier layer 20 may be used. Alternatively, an etchant that does not etch the insulator layer 18 excessively may be used.

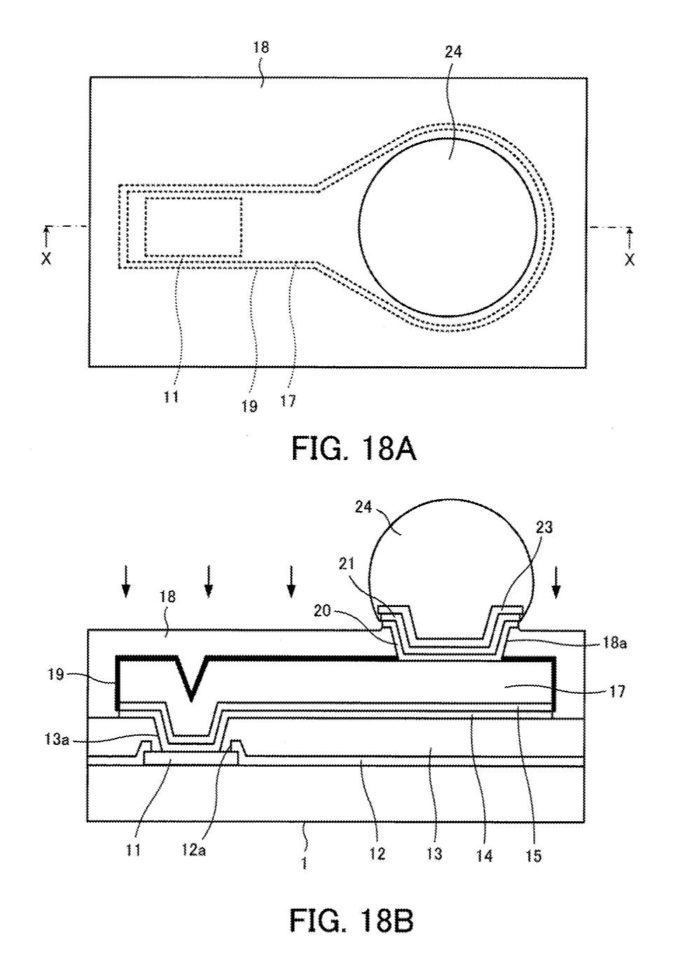

FIGS. 18A and 18B illustrate a step of performing dry etching according to the first embodiment.

After the barrier layer 20 is etched away, the insulator layer 18 appears. The surface of the insulator layer 18 is then dry-etched (illustrated schematically by arrows in FIGS. 18A and 18BB). This dry etching process aims to remove the surface of the insulator layer 18, which has altered when the barrier layer 20 is formed. This dry etching process also aims to remove metal residues which have not been completely removed by etching when the barrier layer 20 is etched. In the dry etching, for example, a mixed gas of oxygen (o₂) and tetrafluorocarbon (CF₄) is used. In this case, the surface of the insulator layer 18 is dry-etched so that the thickness thereof is reduced approximately by 50 nm to 700 nm.

Referring to FIGS. 19A and 19B and FIGS. 20A and 20B, suppose that a reflow process is performed after the barrier layer 20 is etched away. In this case, whether or not the barrier layer 20 is completely etched away has a great impact on the quality of a finished semiconductor device to be formed. Specifically, suppose the following situation: a bump 24 contains Sn, and a barrier layer 20 contains Ti. The etching of the barrier layer 20 is not completed, so Ti is left on the insulator layer 18. If a reflow process is performed in this situation, Sn of the bump 24 adheres to Ti left on the insulator layer 18 during the reflow process. Sn adhering to Ti disturbs dry etching. The dry etching to remove the surface of the insulator layer 18 in this situation may cause the nonuniformity of etching, which means that the etching process is not completed.

In contrast, as illustrated in FIGS. 15A and 15B and FIGS. 16A and 16B, suppose that a reflow process is performed in a condition that the barrier layer 20 is left as it is. In this case, Sn of the bump 24 is scattered during the reflow process, and the scattered Sn adheres to Ti on the surface of the barrier layer 20. The Sn adhering to Ti is removed when the barrier layer 20 is etched away. Therefore, even when the etching of the barrier layer 20 illustrated in FIGS. 17A and 17B is not completed, the dry etching illustrated in FIGS. 18A and 18B is completed successfully.

In the etching step illustrated in FIGS. 15A and 15B, an electrode layer 21 is etched away, but a barrier layer 20 is left on the insulator layer 18. The reason why the electrode layer 21 is etched away completely is as follows. Suppose that the electrode layer 21 is made of Cu, and the bump 24 is made of solder material. If a reflow process is performed with the electrode layer 21 as it is, the Cu becomes wet with the solder material. In this case, the adjustment of the height of the bump 24 may become difficult, and the bump 24 and another bump (not illustrated) may cause a short circuit connection. On the other hand, the barrier layer 20 is less easy to get wet with solder material if the barrier layer 20 is made of Ti, TiW, or the like. This means that the above situation may be avoided. In the first embodiment, as illustrated in FIGS. 15A and 15B, the electrode layer 21 is etched away, but the barrier layer 20 is left unremoved.

As described above, in the first embodiment, in a condition that a barrier layer 20 formed on an insulator layer 18 is left unremoved, a reflow process is performed on a bump 24 by using hydrogen or carboxylic acid. As a result, the permeation of hydrogen or carboxylic acid into the insulator layer 18 is prevented, and the reduction of the oxide film 19 interposed between the redistribution layer 17 and the insulator layer 18 is suppressed. This means that the adhesion between the redistribution layer 17 and the insulator layer 18 is prevented from becoming lower. Also in the first embodiment, after a reflow process, the barrier layer 20 is partially removed from the insulator layer 18, and the insulator layer 18 is then dry-etched so that the surface thereof is removed uniformly. This method achieves a semiconductor device excellent in quality.

Next, a description is given for a second embodiment.

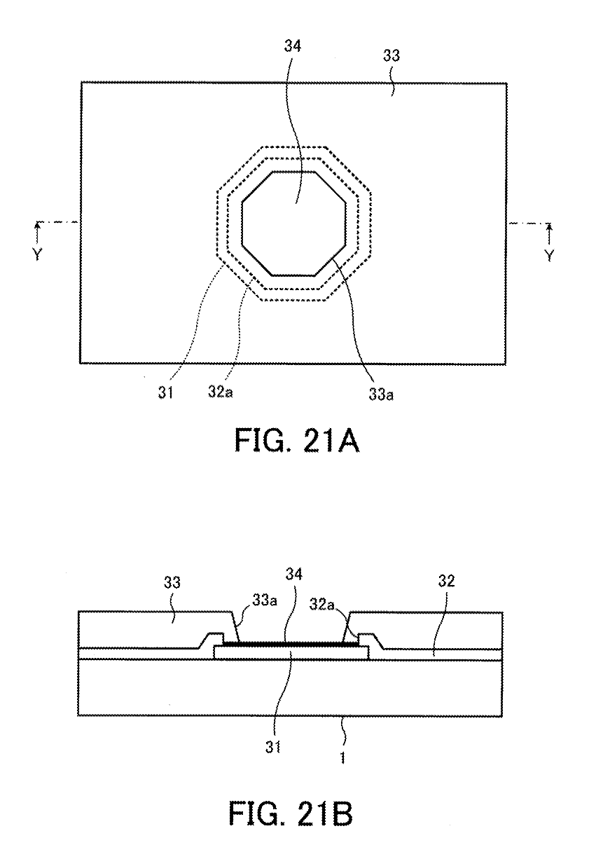

Referring to FIGS. 21A and 21B to 32A and 32B, the second embodiment describes an example in which a pad and a bump are formed over a circuit board 1 illustrated in FIG. 2.

FIGS. 21A and 21B to 32A and 32B schematically illustrate each step of forming a pad and a bump. FIGS. 21A to 32A are plan views of a substantial part of an unfinished semiconductor device during manufacture according to the second embodiment. FIGS. 21B to 32B are sectional views taken along the line Y-Y in FIGS. 21A to 32A. In FIGS. 21A and 21B to 32A and 32B, the internal configuration of the circuit board 1 illustrated in FIG. 2 is omitted for the sake of convenience.

FIGS. 21A and 21B illustrate a step of forming a pad and an insulator layer according to the second embodiment.

First, a pad 31 is formed on a circuit board 1. The pad 31 connects electrically to a corresponding transistor 4 formed in the circuit board 1. The pad 31 is made of Al, Cu, a conductive material containing Al, a conductive material containing Cu, or the like.

After the pad 31 is formed, an insulator layer 32 is formed on the circuit board 1. The insulator layer 32 has an opening 32a so that a region of the pad 31 appears therethrough. The insulator layer 32 is made of, for example, an inorganic insulating material. The insulator layer 32 protects the pad 31 and the circuit board 1.

An insulator layer 33 is formed on the circuit board 1 having the pad 31 and the insulator layer 32 formed thereon. The insulator layer 33 has an opening 33a so that a region of the pad 31 appears therethrough. The insulator layer 33 improves the reliability of a finished semiconductor device to be formed and the electrical characteristics thereof.

The type of the insulator layer 33 may vary according to the reliability of a finished semiconductor device to be formed, the upper temperature limits of the elements in the circuit board 1, and the infrastructure of the factory where the semiconductor device is manufactured. The insulator layer 33 may be made of, for example, an organic insulating material such as polyimide, PBO, or epoxy resin. The insulator layer 33 is formed, for example, by depositing an organic insulating material on the insulator layer 32, and then annealing the organic insulating material in the range of 300° C. to 380° C. in a nitrogen atmosphere containing 100 ppm of oxygen or less.

The thickness of the insulator layer 33 may vary according to the intended use of a semiconductor device to be manufactured. For example, the insulator layer 33 may be 2 μm to 10 μm thick.

When the insulator layer 33 is formed, an oxide film 34 is also formed on a surface of the pad 31. Oxygen sources of the oxide film 34 include the oxygen contained in the environment where the insulator layer is formed (during annealing, etc), the oxygen contained in the insulator layer 33 or the material thereof, and oxygen from the atmosphere. Since the oxide film 34 is interposed between the pad 31 and the insulator layer 33, the adhesion between the pad 31 and the insulator layer 33 is improved in comparison with a case where no oxide film 34 is interposed.

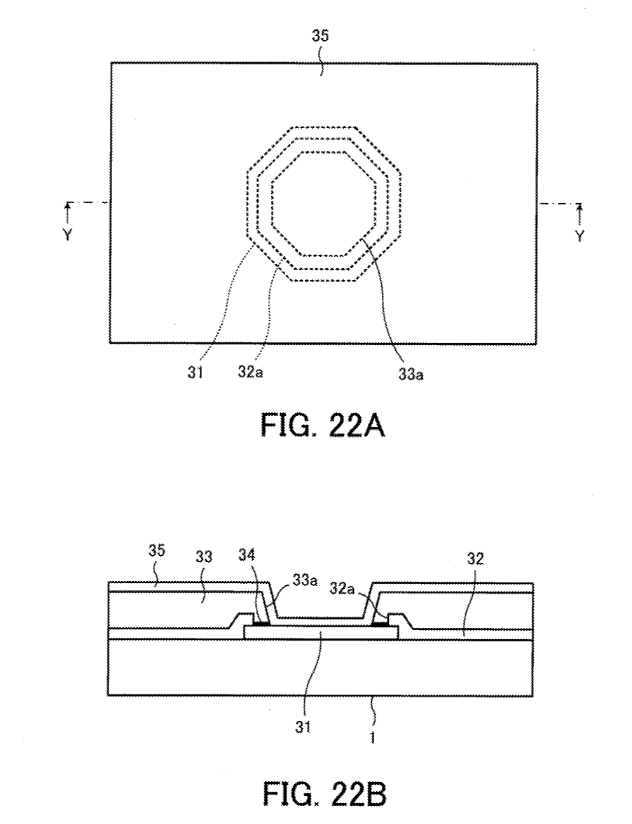

FIGS. 22A and 22B illustrate a step of forming a barrier layer according to the second embodiment.

After the insulator layer 33 is formed, a barrier layer 35 is formed so as to coat the insulator layer 33. The barrier layer 35 is made of, for example, a barrier metal material. The barrier layer 35 serves to prevent undesirable leakage of the material of a bump to be formed later onto the pad 31. The barrier layer 35 also serves to have the interconnection between the bump and the pad 31, and to improve the adhesion therebetween.

Before the barrier layer 35 is formed, the oxide film 34 formed on the pad 31 in the opening 33a is removed. For example, the oxide film 34 is partially removed by reverse sputtering, and the barrier layer 35 is then deposited by sputtering.

The barrier layer 35 is formed on the inner surface of the opening 33a of the insulator layer 33 (specifically, the top face of the pad 31 positioned in the bottom of the opening 13a, and the surface of the sidewalls of the opening 33a of the insulator layer 33), and on the insulator layer 33. The barrier layer 35 is made of, for example, Ti or TiW. The barrier layer 35 is, for example, 100 nm to 300 nm thick. If the barrier layer 35 is thinner than 100 nm, this may cause the nonuniformity of deposition thickness of the barrier layer 35 on the inner surface of the opening 33a, and on the entire surface of the insulator layer 33, depending on the size of the opening 33a. On the other hand, if the barrier layer 35 is thicker than 300 nm, a greater stress is generated in the insulator layer 33 deposited immediately below the barrier layer 35, cracks are likely to occur in the insulator layer 33.

The barrier layer 35 is made of a material which prevents the permeation of hydrogen or carboxylic acid used in a reflow process to be described later.

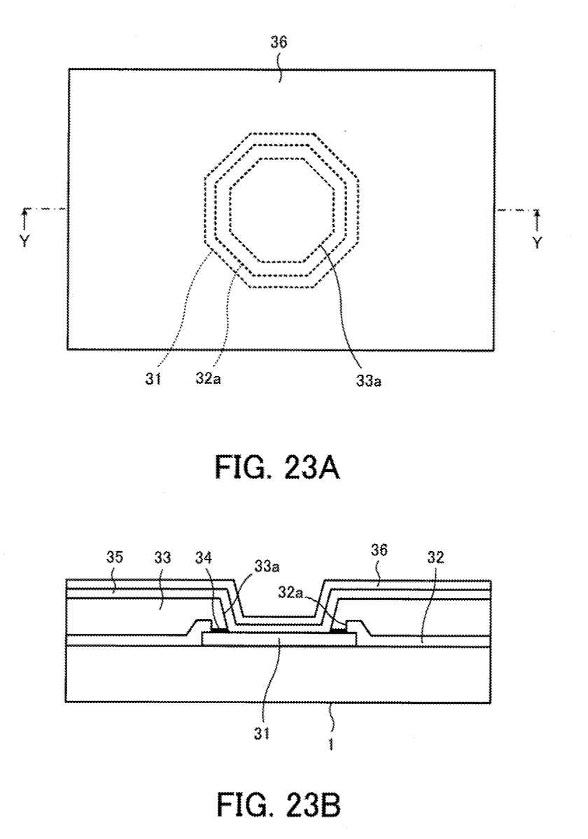

FIGS. 23A and 23B illustrate a step of forming an electrode layer according to the second embodiment.

After the barrier layer 35 is formed, an electrode layer 36 is formed. Electric power is supplied through the electrode layer 36 in an electroplating step to be described later.

The electrode layer 36 is an electrically conductive layer made of Cu or the like, and is formed by a method such as plating or sputtering. The thickness of the electrode layer 36 may cause the nonuniformity of plating thickness, so the thickness of the electrode layer 36 is determined depending on the condition of the base metal (electrode layer 36) before electroplating. The thickness of the electrode layer 36 is, for example, 200 nm to 500 nm.

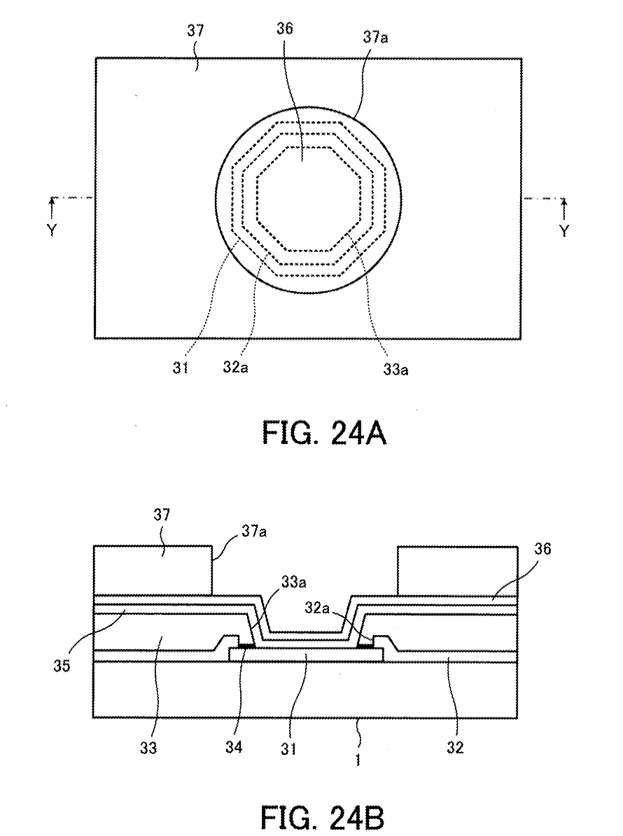

FIGS. 24A and 24B illustrate a step of forming a resist according to the second embodiment.

After the electrode layer 36 is formed, a resist 37 is formed. The resist 37 is formed by depositing a predetermined resist material on the electrode layer 36 with a predetermined thickness. An opening 37a is then formed by exposing and developing the resist 37 so that the region where a bump is to be formed appears therethrough.

The material used as the resist 37 is not limited to a specific type of material, as long as the material fits for the material of the electrode layer 36. In this case, novolac positive resist is employed as the resist 37. The thickness of the resist 37 may vary depending on the heights of a bump, etc. to be formed and their forming conditions.

For example, the thickness of the resist 37 is about 50 μm or thinner. The resist 37 may be liquid or dry film

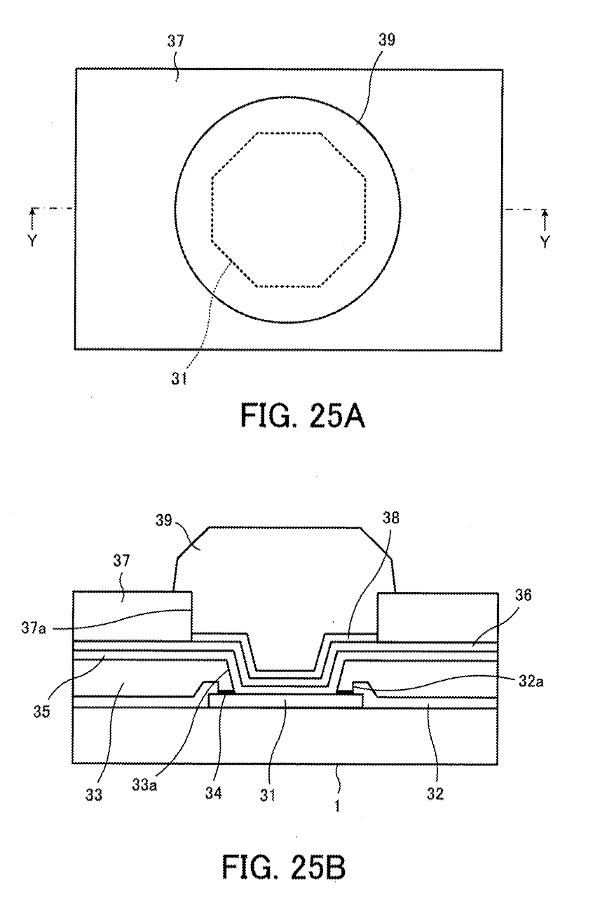

FIGS. 25A and 25B illustrate a step of forming a bump according to the second embodiment.

After the resist 37 and the opening 37a are formed, a UBM 38 and a bump 39 are formed. In this case, both the UBM 38 and the bump 39 are formed by electroplating.

The UBM 38 is formed by electroplating on a region of the electrode layer 36, which appears through the opening 37a of the resist 37. Electric power for the electroplating is supplied through the electrode layer 36. The UBM 38 is made of, for example, Ni. The thickness of the UBM 38 is determined depending on the material of the bump 39 to be formed later. For example, in the case where the bump 39 is formed by soldering, the thickness of the UBM 38 is about in the range of 2 μm to 5 μm. Next, suppose that the UBM 38 is made of Ni, and the bump 39 is formed by soldering. High melting point solder materials have a low Sn level, so the UBM 38 tends to be thinner. On the other hand, tin-silver (SnAg) solder materials have a high Sn level, so the UBM 38 tends to be thicker.

The bump 39 is formed on the UBM 38 in the opening 37a of the resist 37 by electroplating. Electric power for the electroplating is supplied through the electrode layer 36 and the UBM 38. The bump 39 is made of, for example, a solder material. In this case, SnAg solder material is employed. The bump 39 is formed in the opening 37a of the resist 37. The bump 39 is high enough to protrude from the resist 37. The electroplating thickness of the bump 39 is determined depending on the height of the bump 39 to be obtained finally after a reflow process. According to the height of the bump 39 to be obtained finally, electroplating conditions and the thickness (see FIGS. 24A and 24B) of the resist 37 are determined.

The above description relates to the case in which both the UBM 38 and the bump 39 are formed by electroplating. However, a bump may be formed by putting a solder ball on a UBM 38 formed by electroplating. In this case, the thickness of a resist 37 (FIGS. 24A and 24B) for forming the UBM 38 may be 10 μm or thinner.

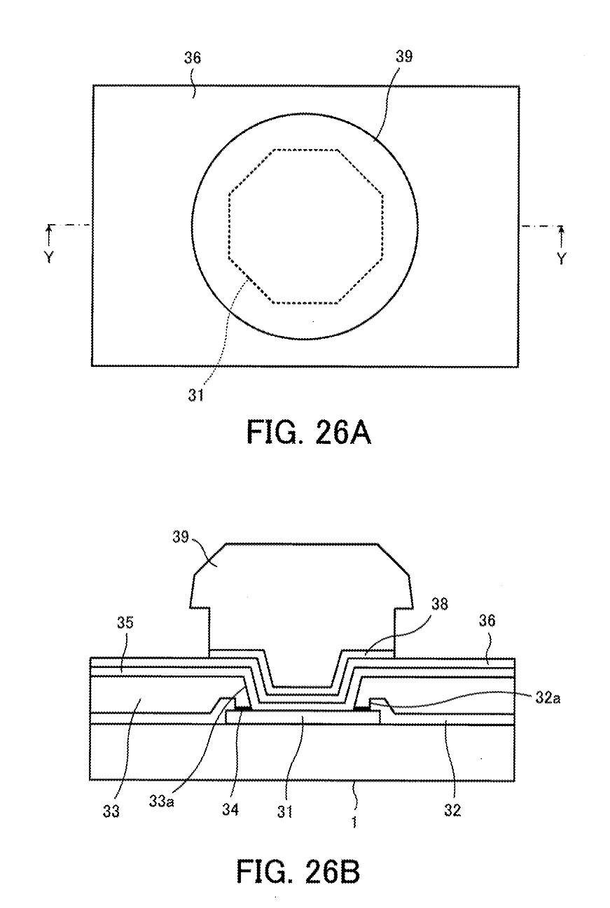

In FIG. 25A and the subsequent FIGS. 26A to 32A, the openings 32a and 33a of the insulator layers 32 and 33 are omitted for the sake of convenience.

FIGS. 26A and 26B illustrate a step of removing the resist according to the second embodiment.

After the UBM 38 and the bump 39 are formed, the resist 37 is stripped from the electrode layer 36. In this case, a stripper which fits for the material of the resist 37 is employed. For example, if a novolac positive resist is employed as the resist 37, butyl acetate, PGME, PGMEA or the like is employed as a stripper. After the resist 37 is stripped, the bump 39, the UBM 38, and the electrode layer 36 appear.

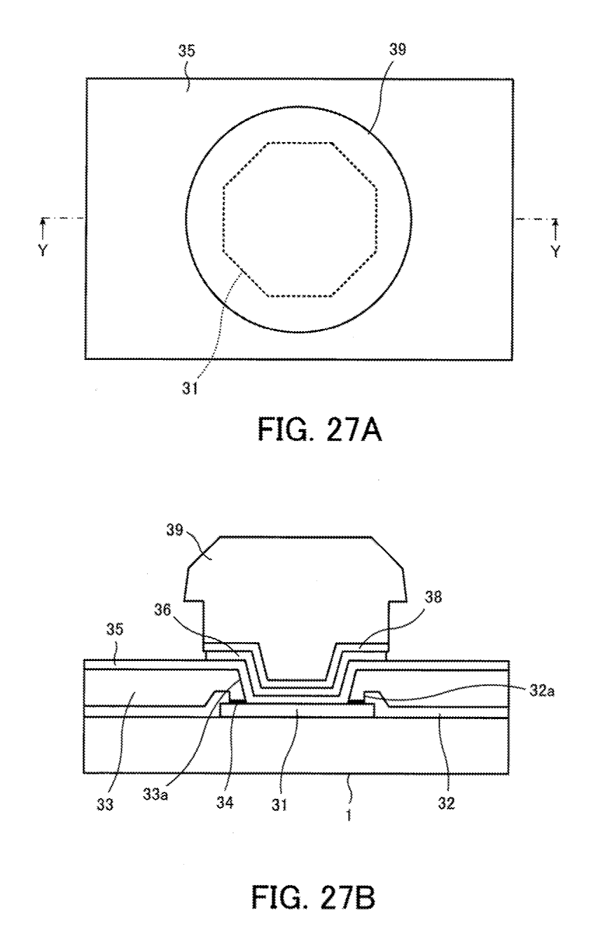

FIGS. 27A and 27B illustrate a step of etching the electrode layer according to the second embodiment.

After the resist 37 is stripped, the electrode layer 36 appears. The electrode layer 36 is then partially removed by etching with the UBM 38 and the bump 39 as masks. This etching process is carried out, for example, by wet etching. The electrode layer 36 is wet-etched with an etchant containing sulfuric acid, acetic acid, and the like. As an etchant for electrode layer 36, an etchant that etches the electrode layer 36 selectively relative to the barrier layer 35 may be used.

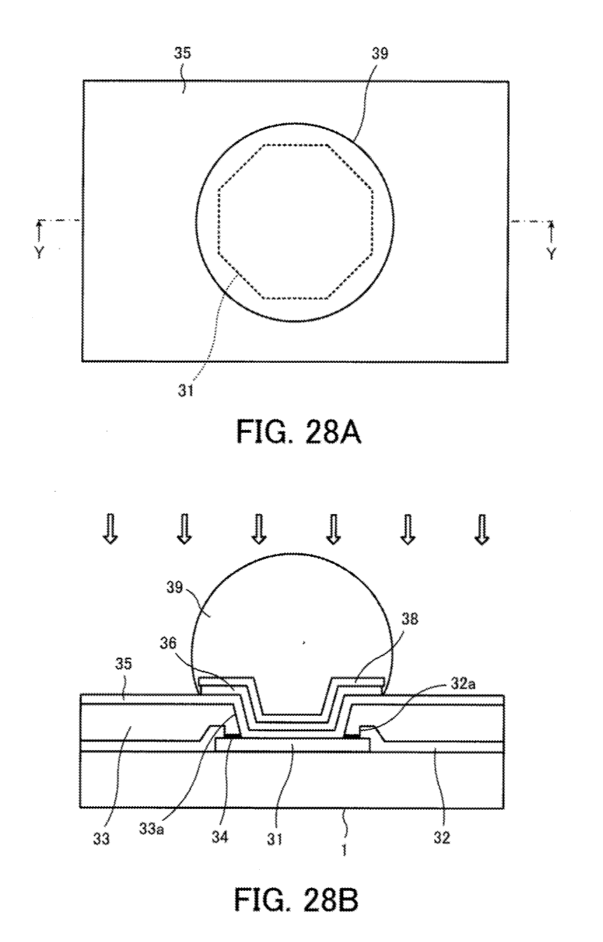

FIGS. 28A and 28B illustrate a step of performing a reflow process according to the second embodiment.

After the electrode layer 36 is partially removed, a reflow process is performed in a condition that the surface of the insulator layer 33 is coated with the barrier layer 35 (illustrated schematically by thick arrows in FIG. 28B). This reflow process is performed in an atmosphere containing hydrogen or carboxylic acid. As mentioned in the first embodiment, examples of carboxylic acid used for the reflow process include formic acid and other various carboxylic acids. Alternatively, any combination of the carboxylic acids may also be used for the reflow process. For example, if formic acid is used as carboxylic acid, a reflow process is performed by the method described in the first embodiment. Immediately after electroplating, the bump 39 has the appearance illustrated in FIGS. 27A and 27B. In the reflow process, the bump 24 is molten, caused to assume a semispherical shape as illustrated in FIGS. 28A and 28B due to surface tension of solder material, and then solidified.

In the second embodiment, in a reflow process using hydrogen or carboxylic acid, an insulator layer 33 is coated with a barrier layer 35. Therefore, the barrier layer 35 prevents the permeation of hydrogen or carboxylic acid used in the reflow process into the insulator layer 33.

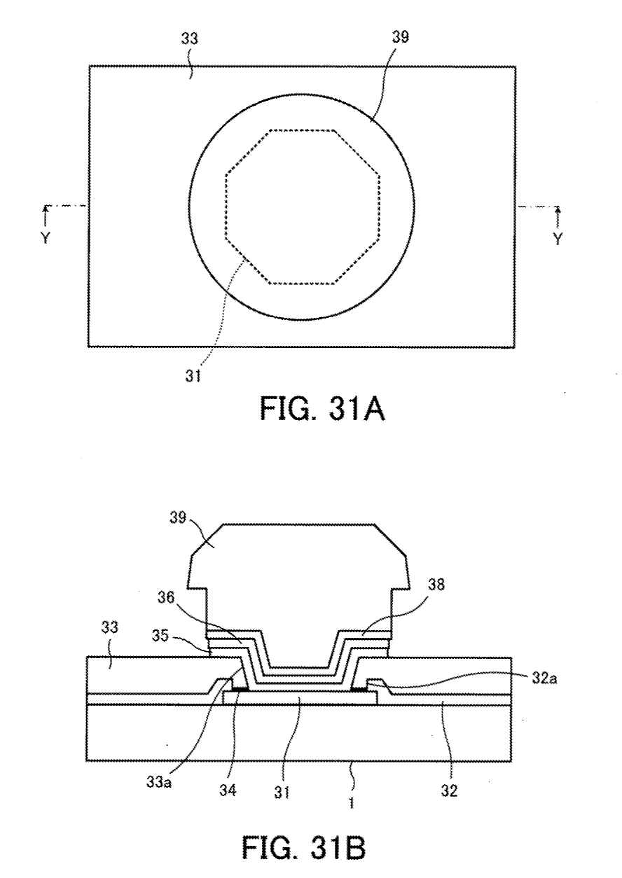

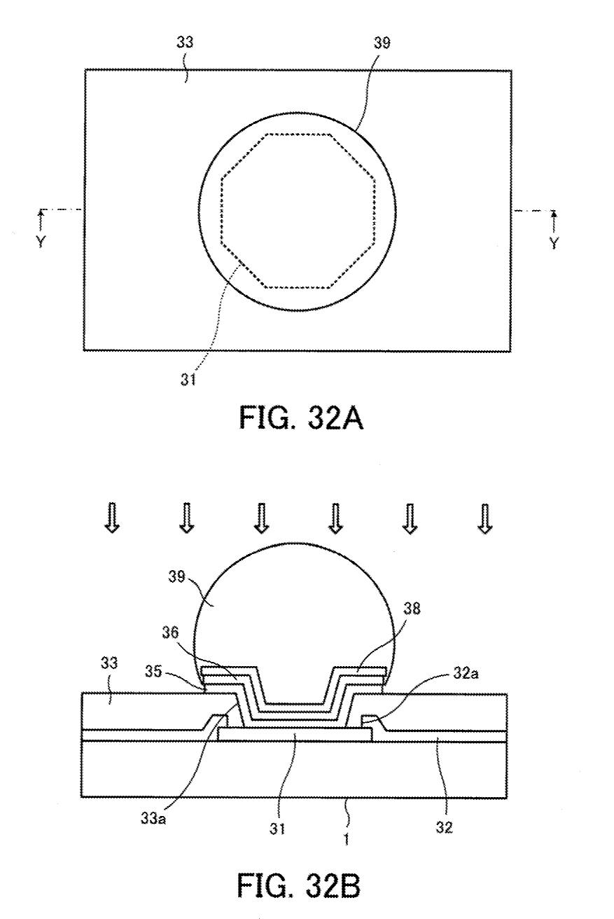

On the other hand, suppose that both the electrode layer 36 and the barrier layer 35 are partially removed from the insulator layer 33 as illustrated in FIGS. 31A and 31B before a reflow process using hydrogen or carboxylic acid. If a reflow process is performed here, a bump 39 is shaped into a semispherical shape as illustrated in FIGS. 32A and 32B. Since the barrier layer 35 is partially removed from the insulator layer 33, the hydrogen or the carboxylic acid used for reflow may permeate into the insulator layer 33 during the reflow process. When the hydrogen or the carboxylic acid reaches an oxide film 34 formed on the surface of a pad 31 through the insulator layer 33, the oxide film 34 may become reduced. Since the oxide film is interposed between the pad 31 and the insulator layer 33, the adhesion between the pad 31 and the insulator layer 33 is relatively high. If the oxide film 34 disappears due to the reduction, the adhesion between the pad 31 and the insulator layer 33 becomes lower.

In contrast, in the second embodiment, as illustrated in FIGS. 27A and 27B, since a barrier layer 35, which appears after the removal of the electrode layer 36, is left on surface of the insulator layer 33, the permeation of the hydrogen or the carboxylic acid used in the reflow process into the insulator layer 33 is prevented. As a result of that, as illustrated in 28A and 28B, since the reduction of the oxide film 34 caused by hydrogen or carboxylic acid is suppressed, the adhesion between the pad 31 and the insulator layer 33 is prevented from becoming lower.

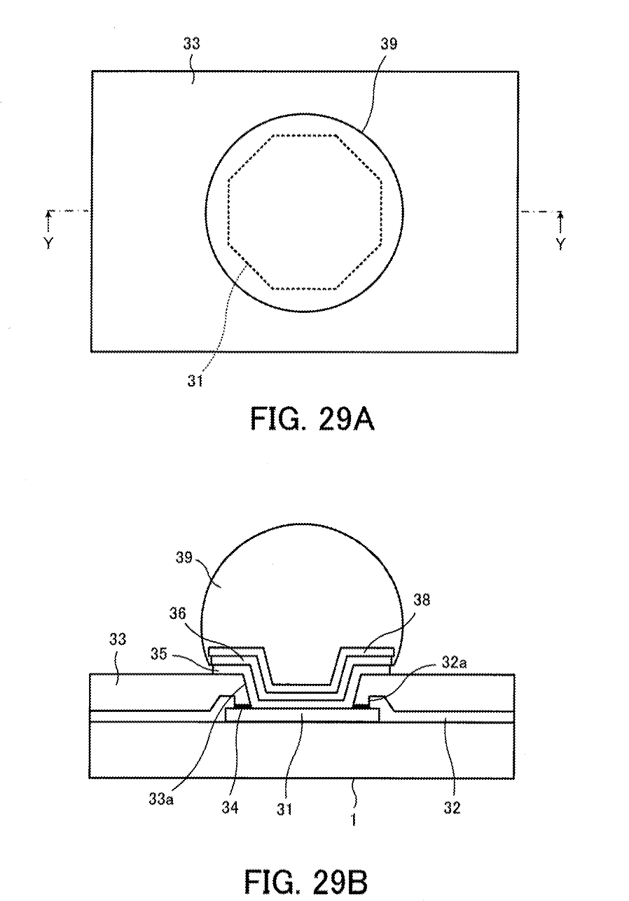

FIGS. 29A and 29B illustrate a step of etching the barrier layer according to the second embodiment.

After the reflow process is performed by using hydrogen or carboxylic acid in a condition that the surface of the insulator layer 33 is coated with the barrier layer 35, the barrier layer 35 is partially removed by etching. This etching process is carried out, for example, by wet etching. The barrier layer 35 is wet-etched with an etchant containing hydrofluoric acid, hydrogen peroxide, and the like. As an etchant for the barrier layer 35, an etchant that does not etch the insulator layer 33 deposited immediately below the barrier layer 35 may be used. Alternatively, an etchant that does not etch the insulator layer 33 excessively may be used.

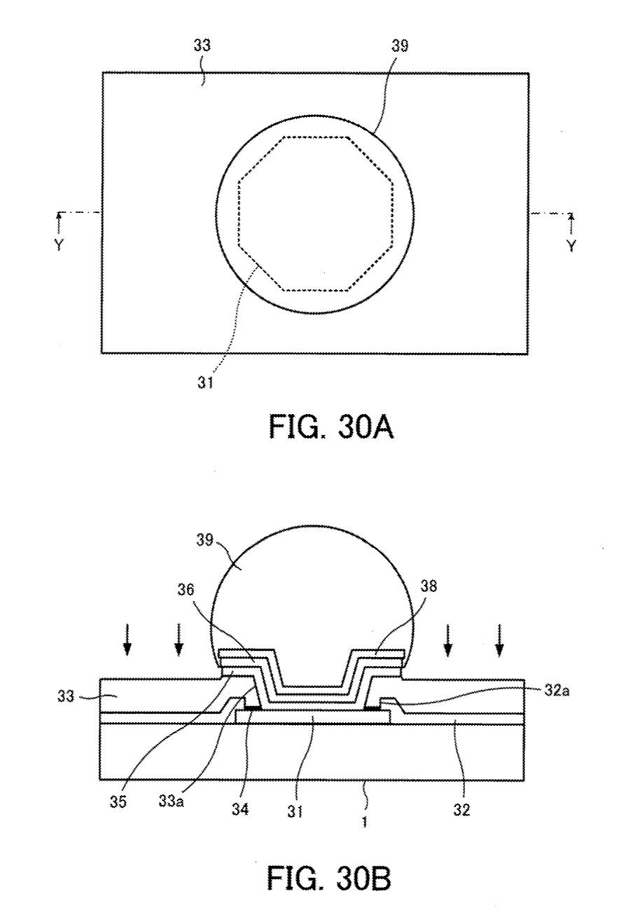

FIGS. 30A and 30B illustrate a step of performing dry etching according to the second embodiment.

After the barrier layer 35 is etched away, the insulator layer 33 appears. The surface of the insulator layer 33 is then dry-etched (illustrated schematically by arrows in FIG. 30B). This dry etching process aims to remove the surface of the insulator layer 33, which has altered when the barrier layer 35 is formed. This dry etching process also aims to remove metal residues which have not been completely removed by etching when the barrier layer 35 is etched away. In the dry etching, for example, a mixed gas of O₂ and CF₄ is used. In this case, the surface of the insulator layer is dry-etched so that the thickness thereof is reduced approximately by 50 nm to 700 nm.

Referring to FIGS. 31A and 31B and FIGS. 32A and 32B, suppose that a reflow process is performed after the barrier layer 35 is etched away. In this case, whether or not the barrier layer 35 is completely etched away has a great impact on the quality of a finished semiconductor device to be formed. Specifically, suppose the following situation: a bump 39 contains Sn, and a barrier layer 35 contains Ti. The etching of the barrier layer 35 is not completed, so Ti is left on the insulator layer 33. If a reflow process is performed in this situation, Sn of the bump 39 adheres to Ti left on the insulator layer 33 during the reflow process. Sn adhering to Ti disturbs dry etching. The dry etching to remove the surface of the insulator layer 33 in this situation may cause the nonuniformity of etching, which means that the etching process is not completed.

In contrast, as illustrated in FIGS. 27A and 27B and FIGS. 28A and 28B, suppose that a reflow process is performed in a condition that the barrier layer 35 is left as it is. In this case, Sn of the bump 39 is scattered during the reflow process, and the scattered Sn adheres to Ti on the surface of the barrier layer 35. The Sn adhering to Ti is removed when the barrier layer 35 is etched away. Therefore, even when the etching of the barrier layer 35 illustrated in FIGS. 29A and 29B is not completed, the dry etching illustrated in FIGS. 30A and 30B is completed successfully.

In the etching step illustrated in FIGS. 27A and 27B, an electrode layer 36 is etched away, but a barrier layer 35 is left on the insulator layer 33. The reason why the electrode layer 36 is etched away completely is as follows. Suppose that the electrode layer 36 is made of Cu, and the bump 39 is made of solder material. If a reflow process is performed with the electrode layer 36 as it is, the Cu becomes wet with the solder material. In this case, the adjustment of the height of the bump 39 may become difficult, and the bump 39 and another bump (not illustrated) may cause a short circuit connection. On the other hand, the barrier layer 35 is less easy to get wet with solder material if the barrier layer 20 is made of Ti, TiW, or the like. This means that the above situation may be avoided. In the first embodiment, as illustrated in FIGS. 27A and 27B, the electrode layer 36 is etched away, but the barrier layer 35 is left unremoved.

As described above, in the second embodiment, in a condition that a barrier layer 35 formed on an insulator layer 33 is left unremoved, a reflow process is performed on a bump 39 by using hydrogen or carboxylic acid. As a result, the permeation of hydrogen or carboxylic acid into the insulator layer 33 is prevented, and the reduction of the oxide film 34 interposed between the pad 31 and the insulator layer 33 is suppressed. This means that the adhesion between the pad 31 and the insulator layer 33 is prevented from becoming lower. Also in the second embodiment, after a reflow process, the barrier layer 35 is partially removed from the insulator layer 33, and the insulator layer 33 is then dry-etched so that the surface thereof is removed uniformly. This method may achieve a semiconductor device excellent in quality.

Next, a description is given for a third embodiment.

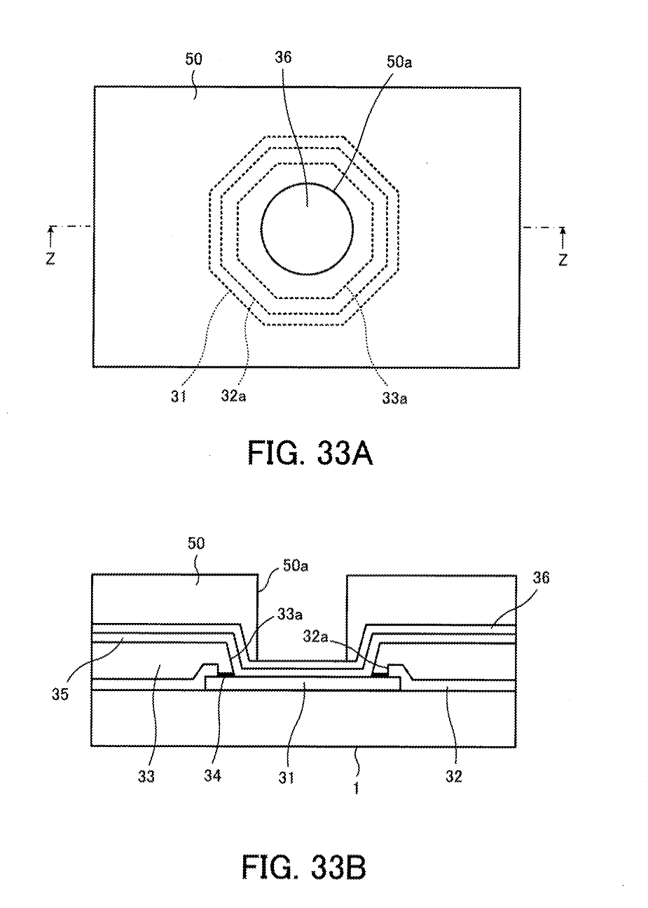

Referring to FIGS. 33A and 33B to FIGS. 41A and 41B, the third embodiment describes an example in which a pad and a pillar bump are formed over a circuit board 1 illustrated in FIG. 2. In the third embodiment, the same steps are taken as the steps corresponding to FIGS. 21A and 21B to FIGS. 23A and 23B described in the second embodiment. Hereinafter, a description is given for steps after the steps illustrated in FIGS. 23A and 23B.

FIGS. 33A and 33B to FIGS. 41A and 41B schematically illustrate each step of forming a pad and a pillar bump. FIGS. 33A to 41A are plan views of a substantial part of an unfinished semiconductor device during manufacture according to the third embodiment. FIGS. 33B to 41B are sectional views taken along the line Z-Z in FIGS. 33A to 41A. In FIGS. 33A and 33B to FIGS. 41A and 41B, the internal configuration of the circuit board 1 illustrated in FIG. 2 is omitted for the sake of convenience.

FIGS. 33A and 33B illustrate a step of forming a resist according to the third embodiment.

As illustrated in FIGS. 21A and 21B to FIGS. 23A and 23B, first, a pad 31, insulator layers 32 and 33, an oxide film 34, a barrier layer 35, and an electrode layer 36 are formed on a circuit board 1. As illustrated in FIGS. 33A and 33B, a resist 50 is then formed. The resist 50 is formed by depositing a predetermined resist material on the electrode layer 36 with a predetermined thickness. An opening 50a is then formed by exposing and developing the resist 50 so that a region where a pillar bump is to be formed appears therethrough. The size of the region is smaller than that of the pad 31.

The material used as the resist 50 is not limited to a specific type of material, as long as the material fits for the material of the electrode layer 36. In this case, a novolac positive resist is employed as the resist 50. The thickness of the resist 50 may vary depending on the height of a pillar bump to be obtained finally and the forming conditions thereof. For example, if a pillar form is formed to have a height of about 25 μm, the thickness of the resist 50 is about 50 μm. The resist 50 may be liquid or dry film.

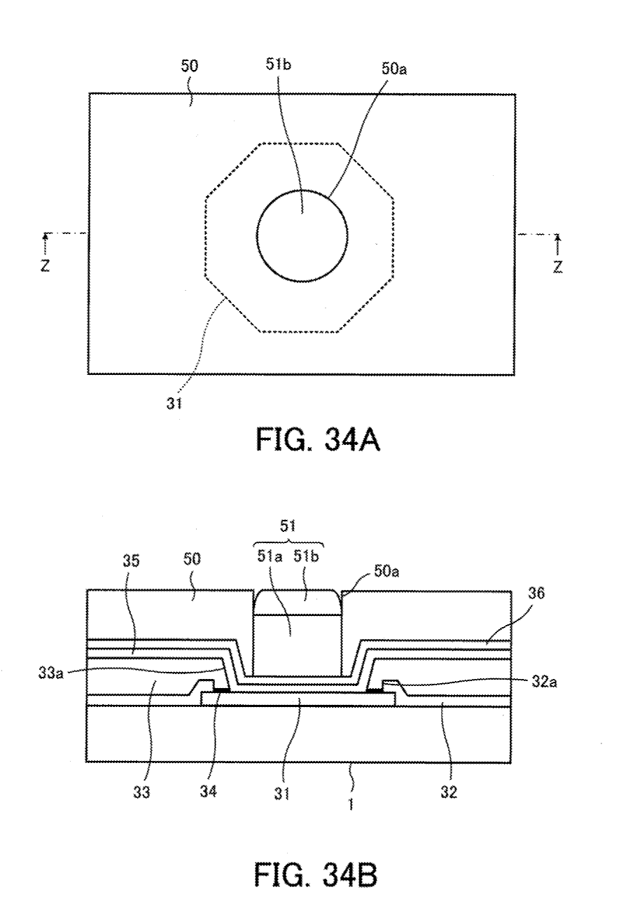

FIGS. 34A and 34B illustrate a step of forming a pillar bump according to the third embodiment.

After the resist 50 and the opening 50a are formed, a pillar 51a and a solder body 51b are formed in the opening 50a to form a pillar bump 51. In this case, both the pillar 51a and the solder body 51b are formed by electroplating.

The pillar 51a is formed by electroplating on a region of the electrode layer 36, which appears through the opening 50a of the resist 50. Electric power for the electroplating is supplied through the electrode layer 36. The pillar 51a is made of, for example, Cu. The solder body 51b is formed in the opening 50a of the resist 50, in which the pillar 51a has been formed by electroplating. Electric power for the electroplating is supplied through the electrode layer 36 and the pillar 51a. In this case, the solder body 51b is made of, for example, SnAg solder material. Although omitted in FIGS. 34A and 34B, a nickel film may be formed as a diffusion barrier film between the pillar 51a and the solder body 51b.

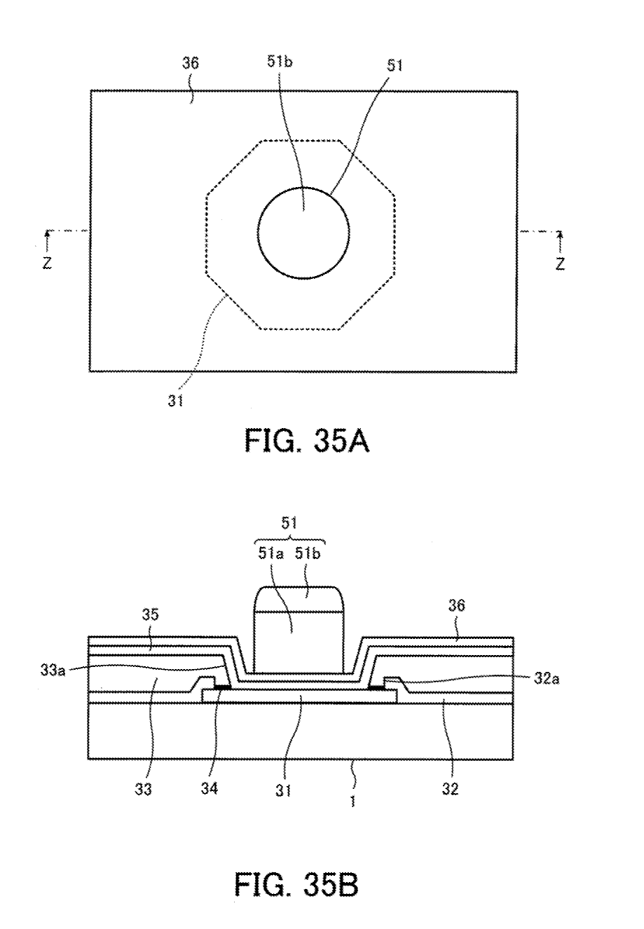

In FIG. 34A and the subsequent FIGS. 35A to 41A, openings 32a and 33a of insulator layers 32 and 33 are omitted for the sake of convenience.

FIGS. 35A and 35B illustrate a step of removing the resist according to the third embodiment.

After the pillar bump 51 is formed, the resist 50 is stripped from the electrode layer 36. In this case, a stripper which fits for the material of the resist 50 is employed. For example, if a novolac positive resist is employed as the resist 50, butyl acetate, PGME, PGMEA or the like is employed as a stripper. After the resist 50 is stripped from the electrode layer 36, the pillar bump 51 and the electrode layer 36 appear.

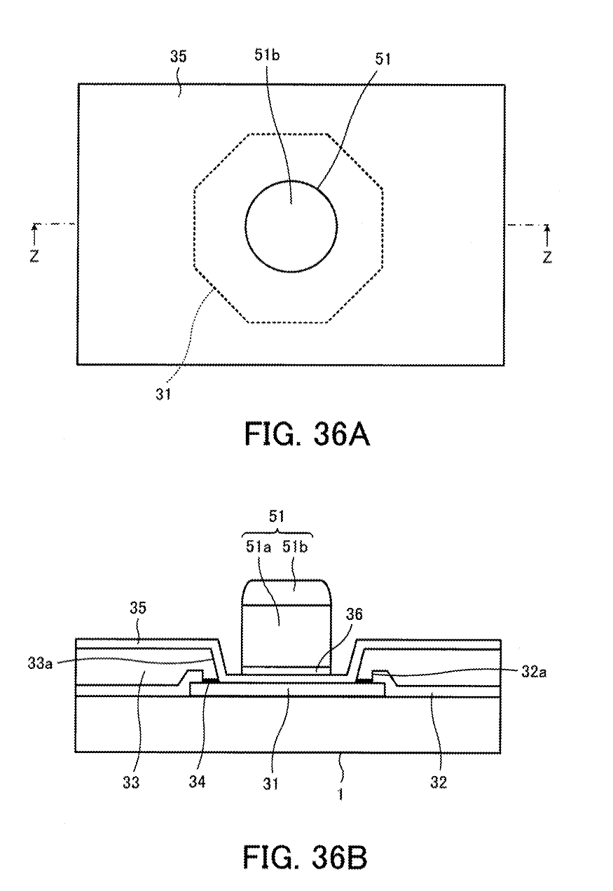

FIGS. 36A and 36B illustrate a step of etching the electrode layer according to the third embodiment.

After the resist 50 is stripped, the electrode layer 36 appears. The electrode layer 36 is then partially removed by etching with the pillar bump 51 as a mask. This etching process is carried out, for example, by wet etching. The electrode layer 36 is wet-etched with an etchant containing sulfuric acid, acetic acid, and the like, for example.

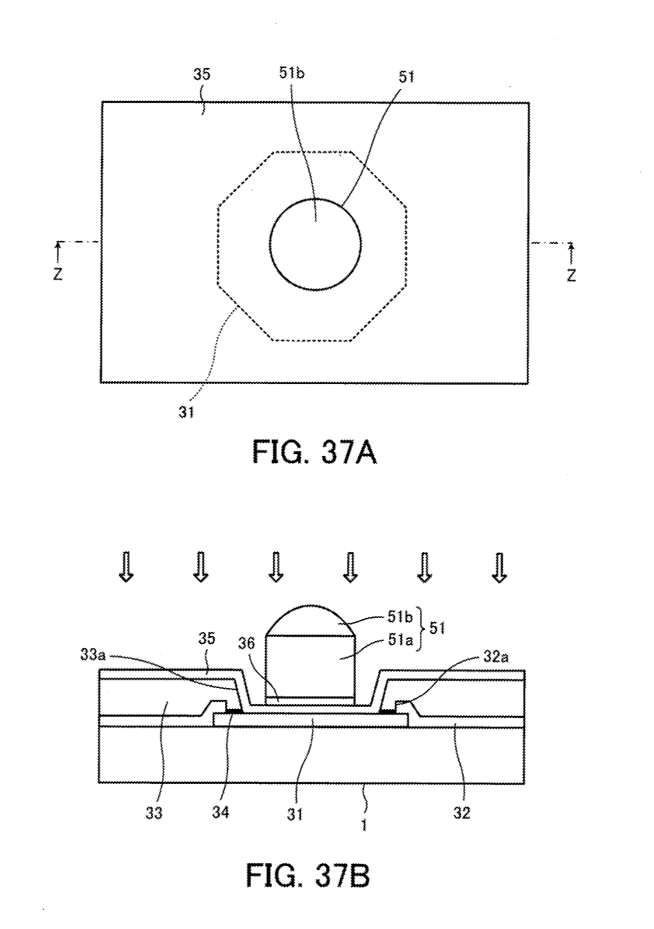

FIGS. 37A and 37B illustrate a step of performing a reflow process according to the third embodiment.

After the electrode layer 36 is partially removed, a reflow process is performed in a condition that the surface of the insulator layer 33 is coated with the barrier layer 35 (illustrated schematically by thick arrows in FIG. 37B). This reflow process is performed in an atmosphere containing hydrogen or carboxylic acid. As mentioned in the first embodiment, examples of carboxylic acid used for the reflow process include formic acid and other various carboxylic acids. Alternatively, any combination of the carboxylic acids may also be used for the reflow process. For example, if formic acid is used as carboxylic acid, a reflow process is performed by the method described in the first embodiment. Immediately after electroplating, the solder body 51b of the pillar bump 51 has the appearance illustrated in FIGS. 36A and 36B. In the reflow process, the solder body 51b is molten, caused to assume a semispherical shape as illustrated in FIGS. 37A and 37B due to surface tension of solder material, and then solidified.

In the third embodiment, in a reflow process using hydrogen or carboxylic acid, an insulator layer 33 is coated with a barrier layer 35. Therefore, the barrier layer 35 prevents the permeation of hydrogen or carboxylic acid used in the reflow process into the insulator layer 33.

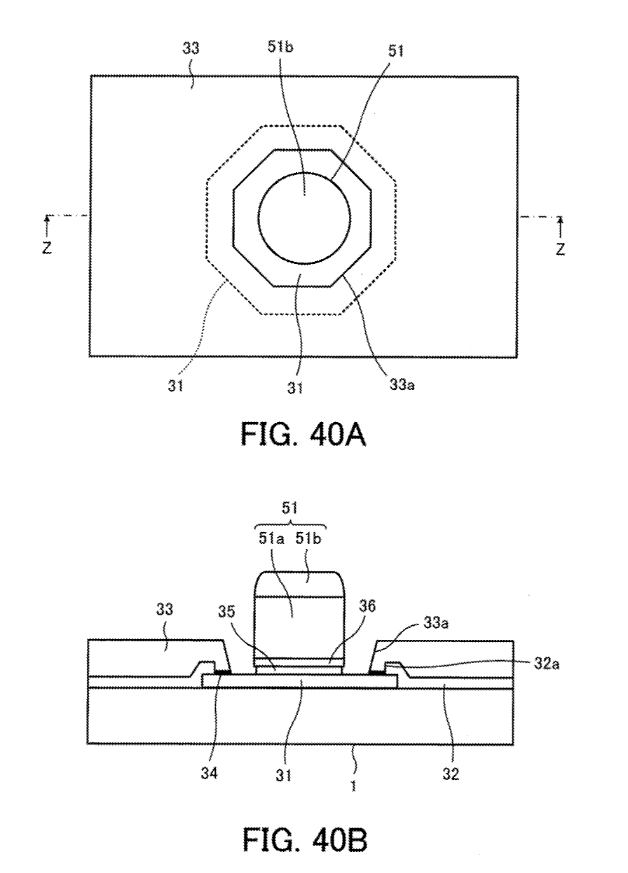

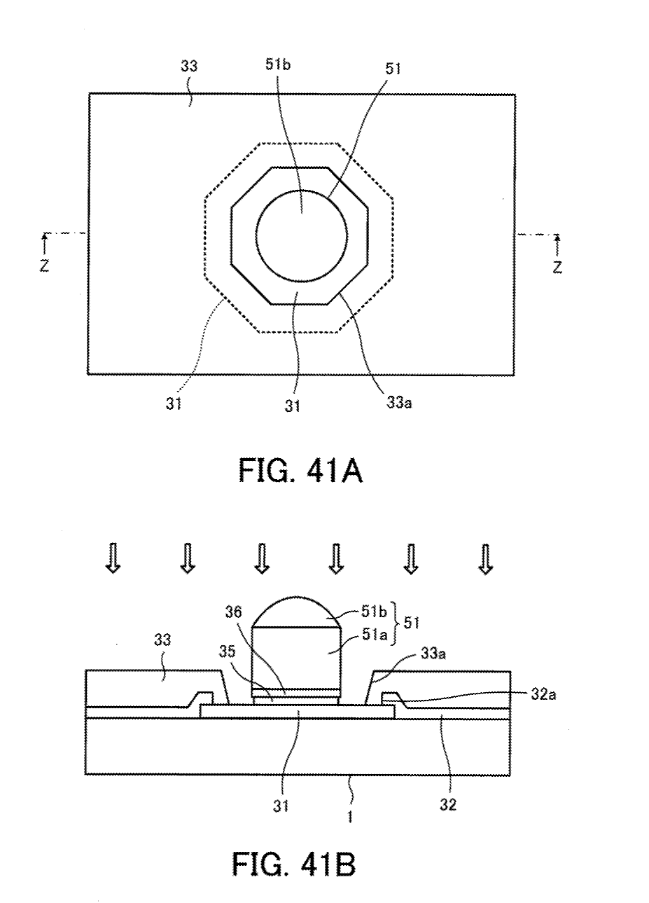

On the other hand, suppose that both the electrode layer 36 and the barrier layer 35 are partially removed from the insulator layer 33 as illustrated in FIGS. 40A and 40B before a reflow process using hydrogen or carboxylic acid. If a reflow process is performed here, a solder body 51b of a pillar bump 51 is shaped into a semispherical shape as illustrated in FIGS. 41A and 41B. Suppose that the hydrogen or the carboxylic acid used for reflow permeates into the insulator layer 33 during the reflow process, and an oxide film 34 disappears due to reduction. In this case, the adhesion between the pad 31 and the insulator layer 33 becomes lower.

In contrast, in the second embodiment, as illustrated in 36A and 36B, since a barrier layer 35, which appears after the removal of the electrode layer 36, is left on surface of the insulator layer 33, the permeation of the hydrogen or the carboxylic acid used in the reflow process into the insulator layer 33 is prevented. As a result of that, as illustrated in 37A and 37B, since the reduction of the oxide film 34 caused by hydrogen or carboxylic acid is suppressed, the adhesion between the pad 31 and the insulator layer 33 is prevented from becoming lower.

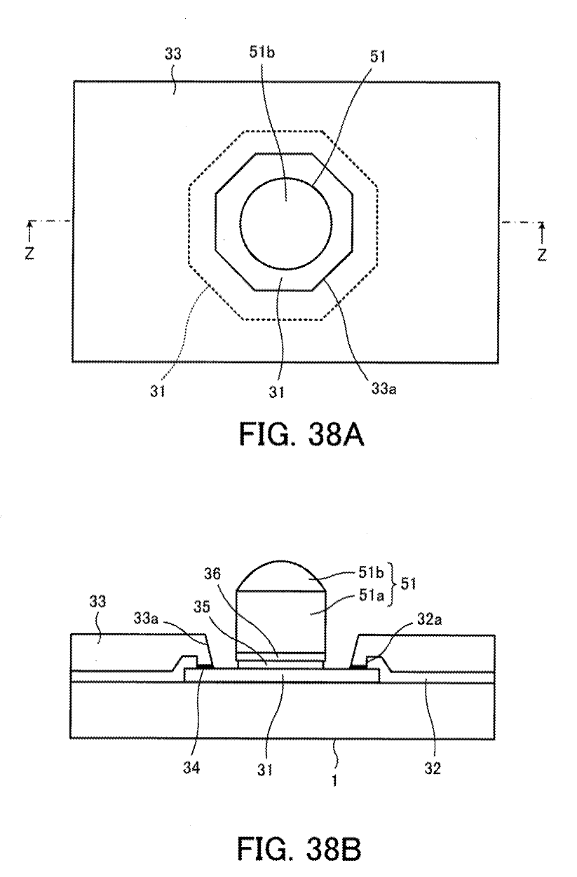

FIGS. 38A and 38B illustrate a step of etching the barrier layer according to the third embodiment.

After the reflow process is performed, the barrier layer 35 is partially removed by etching with the pillar bump 51 as a mask. This etching process is carried out, for example, by wet etching. The barrier layer 35 is wet-etched with an etchant containing hydrofluoric acid, hydrogen peroxide, and the like.

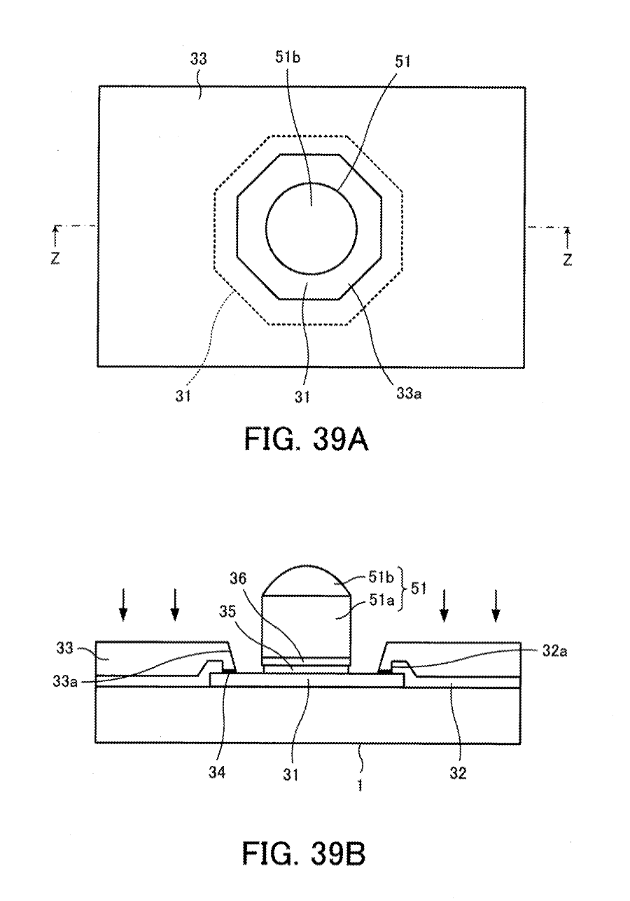

FIGS. 39A and 39B illustrate a step of performing dry etching according to the third embodiment.

After the barrier layer 35 is etched away, the insulator layer 33 appears. The surface of the insulator layer 33 is then dry-etched (illustrated schematically by arrows in FIG. 39B). This dry etching process aims to remove the altered surface of the insulator layer 33, and to remove metal residues.

As described above, in the third embodiment, the same as in the second embodiment, the reduction of the oxide film 34 is suppressed, so that the adhesion between the pad 31 and the insulator layer 33 is prevented from becoming lower. Also, in the third embodiment, after a reflow process and the etching of the barrier layer 35, the insulator layer 33 is then dry-etched so that the surface thereof is removed uniformly. This method achieves a semiconductor device excellent in quality.

In a step of forming a UBM 23 or 38, and a bump 24 or 39 as illustrated in FIGS. 13A and 13B or FIGS. 25A and 25B, if a solder ball is employed to form a bump instead of the bump 24 or 39, the following method may be used.

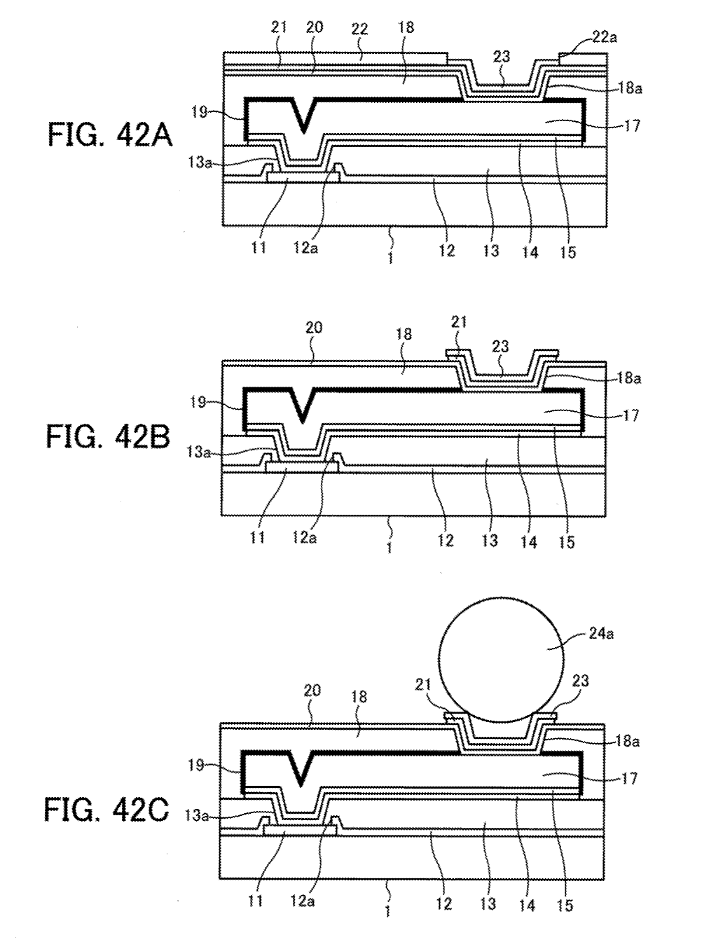

An example is shown based on the first embodiment. As illustrated in FIGS. 42A to 42C, first, a UBM 23 is formed by electroplating in an opening 22a of a resist 22 which is formed relatively thin (FIG. 42A). After the resist 22 is stripped, an electrode layer 21 is partially removed with the UBM 23 as a mask (FIG. 42B). After that, a solder ball 24a is formed on the UBM 23 (FIG. 42C). Subsequently, in an atmosphere containing hydrogen or carboxylic acid, the solder ball 24a is molten and solidified. After that, a barrier layer 20 is partially removed with the solder ball 24a as a mask, and an insulator layer 18 is dry-etched.

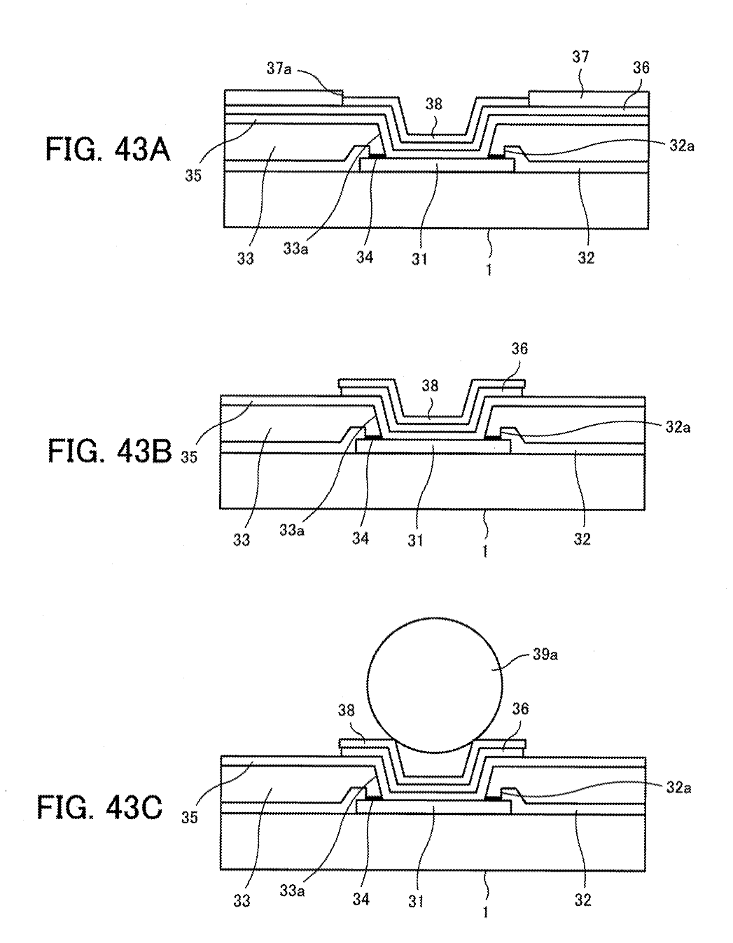

A similar example is shown based on the second embodiment. As illustrated in FIGS. 43A to 43C, first, a UBM 38 is formed by electroplating in an opening 37a of a resist 37 which is formed relatively thin (FIG. 43A). After the resist 37 is stripped, an electrode layer 36 is partially removed with the UBM 38 as a mask (FIG. 43B). After that, a solder ball 39a is formed on the UBM 38 (FIG. 43C). Subsequently, in an atmosphere containing hydrogen or carboxylic acid, the solder ball 39a is molten and solidified. After that, a barrier layer 35 is partially removed with the solder ball 24a as a mask, and an insulator layer 33 is dry-etched.

According to the disclosed method, the adhesion between a conductor and an insulator layer which coats the conductor is prevented from becoming lower. This method achieves a semiconductor device better in quality.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that various changes, substitutions, and alterations could be made hereto without departing from the spirit and scope of the invention.

What is claimed is:

1. A method of manufacturing a semiconductor device comprising:
forming a first insulator layer on a first conductor over a semiconductor substrate;
forming a barrier layer to coat the first insulator layer;
forming a second conductor over the barrier layer;
melting the second conductor in an atmosphere containing either hydrogen or carboxylic acid in a condition that a surface of the first insulator layer is coated with the barrier layer; and
removing the barrier layer partially with the second conductor as a mask.

2. The method of manufacturing a semiconductor device according to claim 1, wherein an oxide film is formed on a surface of the first conductor when the first insulator layer is formed.

3. The method of manufacturing a semiconductor device according to claim 1, wherein the oxide film formed on the surface of the first conductor in the opening is removed when the barrier layer is formed.

4. The method of manufacturing a semiconductor device according to claim 1, wherein the surface of the first insulator layer is dry-etched away after the barrier layer is partially removed from the surface of the first insulator layer.

5. The method of manufacturing a semiconductor device according to claim 1, wherein
an electrode layer is formed on the barrier layer after the barrier layer is formed, and
the second conductor is formed by electroplating using the electrode layer.

6. The method of manufacturing a semiconductor device according to claim 5, wherein the electrode layer is partially removed with the second conductor as a mask after the second conductor is formed and before the second conductor is molten.

7. The method of manufacturing a semiconductor device according to claim 1, wherein the second conductor is formed over the barrier layer in a ball-like shape.

8. The method of manufacturing a semiconductor device according to claim 1, wherein the first conductor is an electrical interconnection formed on a second insulator layer over the semiconductor substrate.

9. The method of manufacturing a semiconductor device according to claim 1, wherein the first conductor is a pad formed on a second insulator layer over the semiconductor substrate.

10. The method of manufacturing a semiconductor device according to claim 1, wherein the first insulator layer is an organic insulator layer.

11. The method of manufacturing a semiconductor device according to claim 1, wherein the barrier layer has a thickness of 100 nm to 300 nm.
